(19) United States
(12) Patent Application Publication
(10) Pub. No.: US 2025/0008792 A1
(43) Pub. Date: Jan. 2, 2025

(54) DISPLAY PANEL AND DISPLAY APPARATUS

(71) Applicant: Wuhan Tianma Micro-Electronics Co., Ltd., Wuhan (CN)

(72) Inventors: Haoyue AN, Wuhan (CN); Qin YUE, Wuhan (CN); Fei LI, Wuhan (CN); Yuehua YANG, Wuhan (CN)

(21) Appl. No.: 18/410,465

(22) Filed: Jan. 11, 2024

(30) Foreign Application Priority Data
Jun. 30, 2023 (CN) 202310804457.7

(51) Int. Cl. H10K 59/131; G09G 3/3258; H10K 59/121

(52) U.S. Cl. CPC H10K 59/131; G09G 3/3258; H10K 59/1213

(57) ABSTRACT

A display panel and a display apparatus are provided in the present disclosure. The display panel includes a display region and a non-display region arranged along a first direction and includes a plurality of first power signal lines. The display region includes a plurality of first data lines extending along the first direction; the non-display region includes a plurality of fan-out lines; and a first data line is electrically connected to a fan-out line through at least one first connection line. A same first connection line includes a first sub-segment and a second sub-segment; one end of the first sub-segment is connected to the first data line, and another end of the first sub-segment is connected to the second sub-segment; the first sub-segment and the first data line are disposed in different layers; and the second sub-segment and the first data line are disposed in a same layer.

### CROSS-REFERENCE TO RELATED APPLICATION

The present disclosure claims the priority of Chinese Patent Application No. 202310804457.7, filed on Jun. 30, 2023, the content of which is incorporated herein by reference in its entirety.

### TECHNICAL FIELD

The present disclosure generally relates to the field of display technology and, more particularly, relates to a display panel and a display apparatus.

### BACKGROUND

Organic light-emitting diode (OLED) is a display technology used in televisions and mobile apparatuses. Compared with existing mainstream liquid crystal displays, OLED display may be one of the most popular display technologies at present because of advantages of self-illumination, low driving voltage, high luminous efficiency, short response time and flexible display.

The OLED elements in the OLED display apparatus may be voltage-driven elements or current-driven elements. For the current-driven element, a corresponding pixel circuit may need to be configured to provide a drive current for the OLED element, such that the OLED element may emit light. The film layer structures for forming the pixel circuits in existing OLED display apparatuses may be complex. In order to avoid the IR drop problem, a conductive film layer may need to be added to form a desirable structure to reduce the IR drop problem. When the driving voltage in the display apparatus is transmitted to the pixel circuit in an effective display region through a wire, the wire may have resistance, such that the driving voltage may produce a direct current voltage drop during the transmission process, that is, IR voltage drop. IR voltage drop may cause final brightness of the display panel to be uneven and affect the display effect. However, disposing additional conductive film layer may inevitably increase additional formation process and cost.

Furthermore, with development of display technology, users may have higher requirements for display products. For example, narrowing of the frames of display products has become a development trend.

Therefore, there is a need to provide a display panel and a display apparatus that may not only avoid adding extra mask processes to save cost, but also improve display effect and achieve narrow frame design.

### SUMMARY

One aspect of the present disclosure provides a display panel. The display panel includes a display region and a non-display region arranged along a first direction, where the display region includes a plurality of first data lines extending along the first direction; the non-display region includes a plurality of fan-out lines; and a first data line of the plurality of first data lines is electrically connected to a fan-out line of the plurality of fan-out lines through at least one first connection line in the display region; and a same first connection line includes a first sub-segment and a second sub-segment which are disposed in different layers; one end of the first sub-segment is connected to the first data line, and another end of the first sub-segment is connected to the second sub-segment; the first sub-segment and the first data line are disposed in different layers; and the second sub-segment and the first data line are disposed in a same layer. The display panel further includes a plurality of first power signal lines, where a same first power signal line includes a first conductive line and a second conductive line which are disposed in different layers; the first conductive line and the second conductive line both extend along the first direction and are electrically connected to each other; and along a direction perpendicular to a plane of the display panel, the first conductive line is at least partially overlapped with the second conductive line; and the first conductive line and the first sub-segment are disposed in a same layer; and the second conductive line and the second sub-segment are disposed in a same layer.

Another aspect of the present disclosure provides a display apparatus including a display panel. The display panel includes a display region and a non-display region arranged along a first direction, where the display region includes a plurality of first data lines extending along the first direction; the non-display region includes a plurality of fan-out lines; and a first data line of the plurality of first data lines is electrically connected to a fan-out line of the plurality of fan-out lines through at least one first connection line in the display region; and a same first connection line includes a first sub-segment and a second sub-segment which are disposed in different layers; one end of the first sub-segment is connected to the first data line, and another end of the first sub-segment is connected to the second sub-segment; the first sub-segment and the first data line are disposed in different layers; and the second sub-segment and the first data line are disposed in a same layer. The display panel further includes a plurality of first power signal lines, where a same first power signal line includes a first conductive line and a second conductive line which are disposed in different layers; the first conductive line and the second conductive line both extend along the first direction and are electrically connected to each other; and along a direction perpendicular to a plane of the display panel, the first conductive line is at least partially overlapped with the second conductive line; and the first conductive line and the first sub-segment are disposed in a same layer; and the second conductive line and the second sub-segment are disposed in a same layer.

Other aspects of the present disclosure may be understood by those skilled in the art in light of the description, the claims, and the drawings of the present disclosure.

### BRIEF DESCRIPTION OF THE DRAWINGS

The accompanying drawings, which are incorporated into a part of the specification, illustrate embodiments of the present disclosure and together with the description to explain the principles of the present disclosure.

FIG. 1 illustrates a planar structural schematic of a display panel according to various embodiments of the present disclosure.

FIG. 2 illustrates a local enlarged structural schematic of a J1 region in FIG. 1.

FIG. 3 illustrates a structural schematic of a part of film layers of a display panel according to various embodiments of the present disclosure.

FIG. 4 illustrates a structural schematic of electrical connection between a pixel circuit and a light-emitting element in a display panel according to various embodiments of the present disclosure.

FIG. 5 illustrates a circuit layout when a pixel circuit structure in FIG. 4 is formed on a substrate of a display panel.

FIG. 6 illustrates a structural schematic of a semiconductive layer in FIG. 5.

FIG. 7 illustrates a structural schematic of a first metal layer in FIG. 5.

FIG. 8 illustrates a structural schematic of a capacitor metal layer in FIG. 5.

FIG. 9 illustrates a structural schematic of a second metal layer in FIG. 5.

FIG. 10 illustrates a structural schematic of a third metal layer in FIG. 5.

FIG. 11 illustrates a structural schematic of two rows of exemplary pixel circuits after a second metal layer and a third metal layer are overlapped in FIG. 5.

FIG. 12 illustrates a structural schematic of a first power signal line and a first connection line in FIG. 11.

FIG. 13 illustrates another structural schematic of a first power signal line and a first connection line in FIG. 11.

FIG. 14 illustrates a structural schematic of a first data line, a first power signal line and a first connection line in FIG. 11.

FIG. 15 illustrates another circuit layout when a pixel circuit structure in FIG. 4 is formed on a substrate of a display panel.

FIG. 16 illustrates a structural schematic of two rows of exemplary pixel circuits after a second metal layer and a third metal layer are overlapped in FIG. 15.

FIG. 17 illustrates a structural schematic of a first data line, a first power signal line and a first compensation signal line in FIG. 16.

FIG. 18 illustrates a structural schematic of a semiconductive layer in FIG. 15.

FIG. 19 illustrates a structural schematic of a first metal layer in FIG. 15.

FIG. 20 illustrates a structural schematic of a capacitor metal layer in FIG. 15.

FIG. 21 illustrates a structural schematic of a second metal layer in FIG. 15.

FIG. 22 illustrates a structural schematic of a third metal layer in FIG. 15.

FIG. 23 illustrates another structural schematic of a first power signal line and a first connection line in FIG. 11.

FIG. 24 illustrates another planar structural schematic of a display panel according to various embodiments of the present disclosure.

FIG. 25 illustrates another planar structural schematic of a display panel according to various embodiments of the present disclosure.

FIG. 26 illustrates another planar structural schematic of a display panel according to various embodiments of the present disclosure.

FIG. 27 illustrates a local enlarged structural schematic of a J2 region in FIG. 26.

FIG. 28 illustrates a structural schematic of a first connection line, a first power signal line, a first data line and a second reference voltage signal line in a circuit layout in FIGS. 5 and 15.

FIG. 29 illustrates a structural schematic of an electrical connection relationship between a first reference voltage signal line and a second reference voltage signal line in a display panel according to various embodiments of the present disclosure.

FIG. 30 illustrates a structural schematic of an electrical connection relationship between a semiconductive layer, a first scanning signal line and a second reference voltage signal line in a display panel according to various embodiments of the present disclosure.

FIG. 31 illustrates another structural schematic of an electrical connection relationship between a first reference voltage signal line and a second reference voltage signal line in a display panel according to various embodiments of the present disclosure.

FIG. 32 illustrates another circuit layout when a pixel circuit structure in FIG. 4 is formed on a substrate of a display panel.

FIG. 33 illustrates a structural schematic of a semiconductive layer in FIG. 32.

FIG. 34 illustrates a structural schematic of a first metal layer in FIG. 32.

FIG. 35 illustrates a structural schematic of a capacitor metal layer in FIG. 32.

FIG. 36 illustrates a structural schematic of a second metal layer in FIG. 32.

FIG. 37 illustrates a structural schematic of a third metal layer in FIG. 32.

FIG. 38 illustrates a structural schematic of two rows of exemplary pixel circuits after a second metal layer and a third metal layer are overlapped in FIG. 32.

FIG. 39 illustrates a structural schematic of four adjacent pixel circuits sequentially arranged after a second metal layer and a third metal layer are overlapped in FIG. 32.

FIG. 40 illustrates a planar structural schematic of a display apparatus according to various embodiments of the present disclosure.

### DETAILED DESCRIPTION

Various exemplary embodiments of the present disclosure are described in detail with reference to accompanying drawings. It should be noted that unless stated otherwise, relative arrangement of assemblies and steps, numerical expressions and values described in those embodiments may not limit the scope of the present disclosure.

Following description of at least one exemplary embodiment may be merely illustrative and may not be configured to limit the present disclosure and its application or use.

The technologies, methods and apparatuses known to those skilled in the art may not be discussed in detail, but where appropriate, the technologies, methods and apparatuses should be considered as a part of the present disclosure.

In all examples shown and discussed herein, any specific value should be interpreted as merely exemplary, rather than as a limitation. Therefore, other examples in exemplary embodiment may have different values.

It is apparent to those skilled in the art that various modifications and variations may be made in the present disclosure without departing from the spirit or scope of the disclosure. Therefore, it is intended that the present disclosure cover the modifications and variations of this disclosure provided they come within the scope of the corresponding claims (claimed technical solutions) and their equivalents. It should be noted that the implementation modes provided by embodiments of the present disclosure may be combined with each other if there is no contradiction.

It should be noted that similar reference numerals and letters are configured to indicate similar items in following drawings. Therefore, once an item is defined in one drawing, it does not need to be further discussed in subsequent drawings.

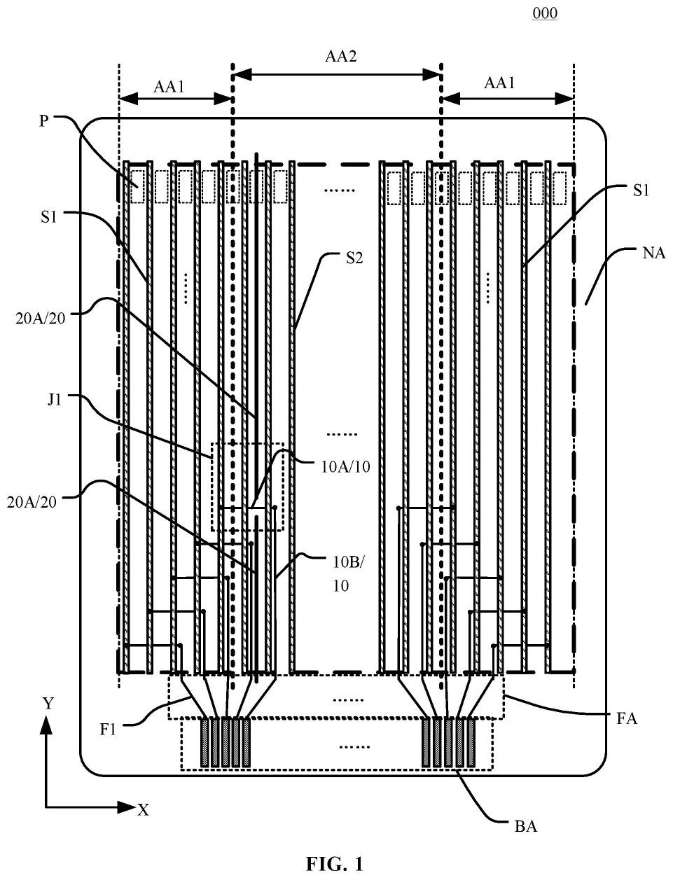

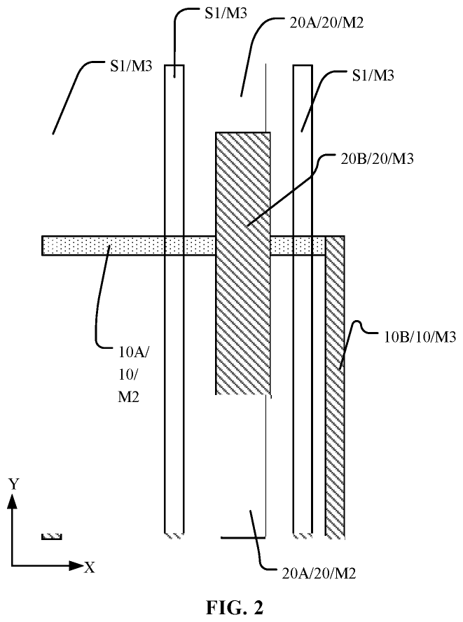

Referring to FIGS. 1-2, FIG. 1 illustrates a planar structural schematic of a display panel according to various embodiments of the present disclosure; and FIG. 2 illustrates a local enlarged structural schematic of a J1 region in FIG. 1. It may be understood that in order to clearly illustrate the structure of one embodiment, transparency filling is performed in FIG. 2. A display panel 000 provided in one embodiment may include a display region AA and a non-display region NA arranged along the first direction Y. The display region AA may include a plurality of first data lines S1 extending along the first direction Y, and the non-display region NA may include a plurality of fan-out lines F1. The first data line S1 may be electrically connected to the fan-out line F1 through at least one first connection line 10, and the first connection line 10 may be in the display region AA. A same first connection line 10 may include a first sub-segment 10A and a second sub-segment 10B. The first sub-segment 10A and the second sub-segment 10B may be disposed in different layers. One end of the first sub-segment 10A may be connected to the first data line S1, and another end of the first sub-segment 10A may be connected to the second sub-segment 10B. The first sub-segment 10A and the first data line S1 may be disposed in different layers, and the second sub-segment 10B and the first data line S1 may be arranged in a same layer. The display panel 000 may further include a plurality of first power signal lines 20. A same first power signal line 20 may include a first conductive line 20A and a second conductive line 20B disposed in different layers. The first conductive line 20A and the second conductive line 20B may both extend along the first direction Y. The first conductive line 20A and the second conductive line 20B may be electrically connected to each other. Along the direction perpendicular to the plane of the display panel 000, the first conductive line 20A and the second conductive line 20B may be at least partially overlapped with each other. The first conductive line 20A and the first sub-segment 10A may be arranged in a same layer, and the second conductive line 20B and the second sub-segment 10B may be arranged in a same layer.

For example, the display panel 000 provided in one embodiment may be an organic light-emitting diode display panel; in the display region AA and the non-display region NA arranged along the first direction Y, the display region AA may include a plurality of sub-pixels P; and each sub-pixel P may include a light-emitting element and a pixel circuit electrically connected to the light-emitting element. The display region AA may include the plurality of first data lines S1 extending along the first direction Y. The first data line S1 may be configured to provide a data voltage signal to the pixel circuit of the sub-pixel P, that is, to provide a driving signal for the display panel 000 to implement the display function. Optionally, the light-emitting element of each sub-pixel P may be an organic light-emitting diode, or a light-emitting device such as a micro-light-emitting diode or a sub-millimeter light-emitting diode, which may not be limited in one embodiment. It may be understood that the type of the display panel 000 may not be limited in one embodiment, and the structure of the display region AA may be set according to the type of the display panel 000. The design structure of the pixel circuit included in the sub-pixel P of the display region AA may be understood with reference to the structure of the display panel in the existing technology, or the description of subsequent embodiments. The non-display region NA of the display panel 000 may be configured to dispose drive circuits, drive signal lines, and the like included in the display panel 000. Optionally, the non-display region NA may include a fan-out region FA and a binding region BA. The fan-out region FA may be disposed with a plurality of fan-out lines F1. The binding region BA may be disposed with a plurality of conductive pads. The fan-out line F1 may be configured to electrically connect the first data line S1 of the display region AA with the conductive pad of the non-display region NA. The conductive pad may be configured for subsequent electrical connection with a driver chip or a flexible circuit board, thereby realizing that the display driving signal and the like may be provided for the display panel 000 through the driver chip or the flexible circuit board.

With development of current display technology, consumers are increasingly pursuing high screen-to-body ratios in display products, especially in small and medium-sized display products. In order to reduce the non-display region and increase the display region, fan-out lines are designed to be aggregated toward the binding region to form the fan-out region. A large number of fan-out lines may be disposed in the fan-out region, which are configured to output the display driving signal in the driver chip to the data lines in the display region through the fan-out lines. Therefore, the fan-out region occupies a large region which may result in a large width of the fan-out region, and the frame of the display panel may not be further reduced, thereby being difficult to achieve narrow frame design. In addition, for high-resolution and high-definition display products, the number of data signal channels may be larger. Even if extreme processing technology is used in the existing technology, there is not sufficient space to design according to conventional design manner of connecting fan-out lines with data lines in the display region in a one-to-one correspondence in the fan-out region. New design solutions needs be developed to satisfy customer demands for products with narrow frame specification.

In order to solve above problem, in one embodiment, it configures that the non-display region NA may include the plurality of fan-out lines F1; the first data line S1 may be electrically connected to the fan-out line F1 through at least one first connection line 10; the first connection line 10 may be in the display region AA; and two ends of the first connection line 10 may be respectively connected to the fan-out line F1 of the non-display region NA and the first data line S1 of the display region AA. Optionally, along the second direction X in the display panel 000, the display region AA may include a second display region AA2 and a first display region AA1 which are on opposite sides of the second display region AA2. The first direction Y may intersect the second direction X along the direction in parallel with the plane where the display panel 000 is located. In FIG. 1 of one embodiment, the first direction Y and the second direction X may be perpendicular to each other along the direction in parallel with the plane where the display panel 000 is located, which may be taken as an example for illustration. In one embodiment, the first display region AA1 may be understood as the display region adjacent to two edge sides of the display panel 000 along the second direction X, and the second display region AA2 may be understood as the region relatively adjacent to the center of the display region AA. In the display panel 000, the plurality of first data lines S1 extending along the first direction Y may be disposed in the first display region AA1. The first data line S1 may be electrically connected to the fan-out line F1 of the non-display region NA through the first connection line 10 in the display region AA, and the fan-out line F1 may be electrically connected to the conductive pad of the binding region BA. In such way, signal transmission between the first data line S1 and the conductive pad may be achieved. Optionally, the second display region AA2 of the display panel 000 may include a plurality of second data lines S2. One end of the second data line S2 may be directly and electrically connected to other fan-out lines in the non-display region NA within the region corresponding to the second display region AA2.

In one embodiment, the first connection line 10 may be disposed in the display region AA. That is, in one embodiment, when the first data line S1 in the first display region AA1 adjacent to two edge sides of the display panel 000 along the second direction X is electrically connected to the electrical pad of the binding region BA, electrical connection may be achieved through the first connection line 10 in the display region AA, which may prevent the first connection line 10 from occupying the space of the non-display region NA. As shown in FIG. 1, part of segments of the first connection line 10 (e.g., the first sub-segment 10A illustrated in FIG. 1) may gradually extend along the direction of the second display region AA2 within the range of the display region AA, and then extend to the boundary position between the display region AA and the non-display region NA, such that the connection point between the first connection line 10 and the fan-out line F1 may be far away from the first display region AA1 as possible along the second direction X. Compared with the solution in the existing technology, the structure of disposing the first connection line 10 in the display region AA in one embodiment may be beneficial for reducing the width occupied by the multiple fan-out lines F1 along the second direction X, thereby further reducing the lower frame of the display panel 000.

It may be understood that, in one embodiment, the design structure that the first connection line 10 is in the display region AA may satisfy high resolution requirement of the display panel 000. Even if the number of data lines included in the display region AA is larger, the first connection line 10 may be wired from the display region AA, which may reduce the space of the non-display region NA along the second direction X occupied by the fan-out line F1 connected to the first connection line 10. Therefore, the width of the non-display region NA along the second direction X may still be further reduced, which may also ensure display function and achieve narrow frame while satisfying high-resolution requirement.

Another film layer may be used to fabricate the first connection line 10 in the display region AA; for example, a conductive film layer may be added above the film layer where the first data line S1 of the display panel 000 is located to fabricate the first connection line 10. Such manner may ensure that disposing the first connection line 10 does not interfere with original structure of the panel as possible. However, after adding the conductive film layer, the thickness of the panel may increase which may not be beneficial for thinning the display panel, and additional process steps may increase fabrication cost. Moreover, in newly added film layer, additional design may be needed for the region where the first connection line 10 is not disposed to avoid large display effect difference in different regions. On such basis, in order to save fabrication cost and reduce process steps, the first connection line 10 in the display region AA may be directly moved downward. The first connection line 10 may be formed using the conductive film layer included in the display panel itself. For example, a part of segments of the first connection line 10 may be in a same layer as the first data line S1, and a part segment of the first connection line 10 may be in a same layer as the power signal line in the display panel 000. In such way, cost may be saved, but the display effect may be greatly affected. Once a part of segments of the first connection line 10 is in a same layer as the power signal line in the display panel 000, the film layer where the power signal line is located may have more conductive structures to be relatively aggregated; and the wiring space of the film layer may be limited. Under same pixel size, the number of wires may increase, which may limit the line widths of the wires. In particular, limited space may limit the line width reduction of the power signal line. In addition, the length of the power signal line remains unchanged (the size or length of a same panel). Therefore, the impedance of the power signal line may increase, and the voltage uniformity of the power signal line (reflected in the voltage drop (IR drop) of the power signal line) may become worse, which may easily cause uneven display, greatly affect the display quality, and result in the problem of being unable to balance display quality with saving fabrication cost and improving process efficiency.

In order to solve above problem, in one embodiment, when forming the first connection line 10 in the display region AA, a same first connection line 10 may be configured to include the first sub-segment 10A and the second sub-segment 10B; the first sub-segment 10A and the first data line S1 may be disposed in different layers; and the second sub-segment 10B and the first data line S1 may be disposed in a same layer. It may be understood that in drawings of one embodiment, same filling pattern represents disposing in a same layer, and different filling patterns represent disposing in different layers. That is, the second sub-segment 10B of the first connection line 10 may be fabricated using the film layer that already exists in the display panel 000 itself and where the first data line S1 is located. Since the first sub-segment 10A and the first data line S1 are disposed in different layers, one end of the first sub-segment 10A may be electrically connected to the first data line S1 through at least one via hole. The second sub-segment 10B and the first sub-segment 10A are disposed in different layers, and another end of the first sub-segment 10A may be electrically connected to the second sub-segment 10B through at least one via hole. The second sub-segment 10B and the first data line S1 may be disposed in a same layer as, and the second sub-segment 10B may be directly connected to one end of the first data line S1. The display panel 000 may further include the plurality of first power signal lines 20. The first power supply signal line 20 may be understood as a positive power supply signal line configured to provide a positive power supply signal to the pixel circuit of each sub-pixel P in the display region AA. In one embodiment, it configures that same first power signal line 20 may include the first conductive line 20A and the second conductive line 20B disposed in different layers. The first conductive line 20A and the second conductive line 20B may both extend along the first direction Y. That is, although same first power signal line 20 includes the first conductive line 20A and the second conductive line 20B of different film layers, both the first conductive line 20A and the second conductive line 20B may extend along a same direction, that is, extend along the first direction Y.

The first conductive line 20A of the first power signal line 20 and the first sub-segment 10A of the first connection line 10 may be disposed in a same layer; and the second conductive line 20B of the first power signal line 20 and the second sub-segment 10B of the first connection line 10 may be disposed in a same layer. That is, the first sub-segment 10A and the second sub-segment 10B of different film layers included in the first connection line 10 may be both fabricated with the film layer that already exists in the display panel 000 itself and where the first power signal line 20 is located. In such way, new conductive film layer may not be needed in the display panel 000 to fabricate the first connection line 10, which may avoid adding extra mask processes and reduce process steps, thereby being beneficial for saving overall fabrication cost of the display panel 000 and improving process efficiency. Moreover, in one embodiment, it avoids that additional conductive film layer is disposed in the display panel 000 to fabricate the first connection line 10. Therefore, it may avoid the coupling problem between new conductive film layer and the conductive structure in the existing film layer of the panel after additional conductive film layer is disposed in the display panel 000 to fabricate the first connection line 10, which may affect the load of a part of the display region AA. Disposing additional conductive film layer may not only easily increase wiring design difficulty, but also easily affect display quality.

Furthermore, in one embodiment, it configures that the first conductive line 20A and the second conductive line 20B in different film layers in same first power signal line 20 may be electrically connected to each other. Optionally, the first conductive line 20A and the second conductive line 20B in different film layers may be electrically connected to each other through at least one via hole. The impedance of same first power signal line 20 may be reduced by electrically connecting the first conductive line 20A and the second conductive line 20B through different conductive film layers, which may prevent reduced voltage uniformity of the first power signal line 20 due to excessive impedance of the first power signal line 20, thereby being beneficial for improving voltage uniformity of the first power signal line 20 and display uniformity of the display panel 000. In addition, along the direction perpendicular to the plane of the display panel 000, the first conductive line 20A and the second conductive line 20B disposed in different layers in same first power signal line 20 may be at least partially overlapped with each other, which may further effectively improve the problem of relatively large impedance caused by relatively thin width of the first power signal line 20 due to space limitation. The width of the first power signal line 20 itself may be appropriately increased by overlapping the first conductive line 20A and the second conductive line 20B (as long as the width increase does not affect other conductive structures in same layer), which may effectively reduce the impedance of the first power signal line 20 itself and avoid reduced voltage uniformity of the first power signal line 20 due to reduction of the line width of the first power signal line 20. Furthermore, the voltage uniformity problem of the first power signal line 20 may be effectively improved, which may be beneficial for improving display uniformity of the display panel 000 and further improving display quality.

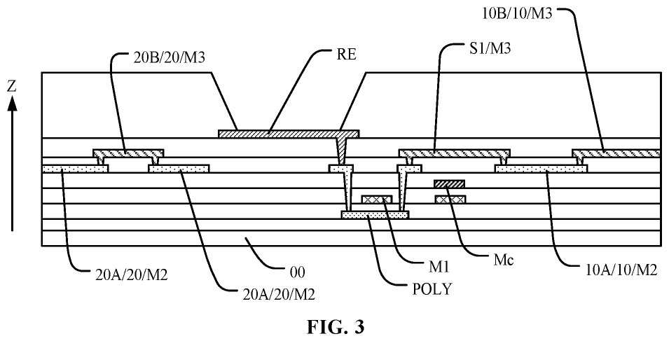

Optionally, referring to FIGS. 1-3, FIG. 3 illustrates a structural schematic of a part of film layers of the display panel according to various embodiments of the present disclosure. It may be understood that in order to clearly illustrate the film layer structure of the display panel, FIG. 3 may only illustrate the film layer positions of the first connection line 10, the first power signal line 20 and the first data line S1 along the longitudinal direction perpendicular to the plane direction Z of the display panel, which may not indicate the positional relationship between above three lines along the horizontal direction, that is, the direction in parallel with the plane of the display panel. The film layer structure of the display panel 000 in one embodiment may include a substrate 00, a semiconductive layer POLY on one side of the substrate 00, a first metal layer M1, a capacitive metal layer Mc, a second metal layer M2, a third metal layer M3, and an anode metal layer RE. The active portion of the thin film transistor included in the pixel circuit may be in the semiconductive layer POLY, the gate electrode of the thin film transistor may be in the first metal layer M1, and the source and drain electrode of the thin film transistor may be in the second metal layer M2. Two terminals of the capacitor included in the pixel circuit may be in the first metal layer M1 and the capacitor metal layer Mc respectively. The first data line S1 and the second data line S2 may be in the third metal layer M3. The first conductive line 20A of the first power signal line 20 may be in the second metal layer M2. The second conductive line 20B of the first power signal line 20 may be in the third metal layer M3. The anode metal layer RE may be configured to fabricate the anode of each sub-pixel P. It may be understood that, in one embodiment, the film layer structure and light-emitting principle of the sub-pixel P in the display panel 000 may not be described in detail and may refer to the film layer structure of the organic light-emitting diode display panel in the existing technology.

It may be understood that the first data line S1 and the second data line S2 in one embodiment may be in the third metal layer M3. Along the direction perpendicular to the substrate 00, the film layer where the data line is located may be further away from the film layer where the driving transistor DT is located, which may be beneficial for reducing signal crosstalk between the data line and the gate connection structure of the driving transistor DT, improving stability of the gate signal of the driving transistor DT and improving display effect.

In the display panel 000 provided by one embodiment, the display region AA may be disposed with the first connection line 10 electrically connecting the first data line S1 and the fan-out line F1; the first sub-segment 10A and the second sub-segment 10B may be included in same first connection line 10; the first sub-segment 10A and the first data line S1 of the third metal layer M3 may be disposed in different layers; and the first conductive line 20A of the first power signal line 20 and the first sub-segment 10A of the first connection line 10 may be disposed in a same layer. That is, the first sub-segment 10A of the first connection line 10 may be fabricated using the second metal layer M2 that is already included in the display panel 000 itself and where the first conductive line 20A of the first power signal line 20 is located. The second sub-segment 10B may be disposed in a same layer as the first data line S1, and the second conductive line 20B of the first power signal line 20 may be disposed in a same layer as the second sub-segment 10B of the first connection line 10. Therefore, the second sub-segment 10B of the first connection line 10 may be fabricated using the third metal layer M3, where the third metal layer M3 is already included in the display panel 000 itself, and the second conductive line 20B of the first power signal line 20 and the first data line S1 are located in the third metal layer M3. It should be known that the first sub-segment 10A and the second sub-segment 10B of different film layers included in the first connection line 10 provided in the display region AA may be fabricated using the film layer that already exists in the display panel 000 itself. Additional film layer may not need to be disposed in the display panel 000 to fabricate the first connection line 10 in the display region AA, which may achieve narrow frame design and avoid adding extra mask processes and reduce process steps, thereby being beneficial for saving overall fabrication cost of the display panel 000 and improving process efficiency. Moreover, the impedance of the first power signal line 20 may be reduced through the second metal layer M2 and the third metal layer M3 included in the display panel 000 itself. In such way, it effectively ensures the line width of the first power signal line 20, which may be beneficial for improving voltage uniformity of the first power signal line 20 by increasing the line width of the first power signal line 20, preventing reduced voltage uniformity of the first power signal line 20 due to impedance increase of the first power signal line 20 which may affect display uniformity, and further satisfying the requirement for improving display quality. Therefore, the display panel 000 provided in one embodiment may not only satisfy narrow frame design, but also achieve the purpose of reducing fabrication cost and improving display quality.

By comparing the voltage uniformity of the first power signal line 20 under different design solutions of the display panel, following experimental data had been obtained. The first connection line in the display region may be directly moved downward to another film layer and may be formed using the conductive film layer included in the panel itself. For example, a part of segments of the first connection line may be in a same layer as the first data line, and a part of segments of the first connection line may be in a same layer as the first power signal line in the display panel. Although cost is saved, once the part of segments of the first connection line is in a same layer as the first power signal line in the display panel, the film layer structure where the first power signal line is located may be excessively large, such that wiring space may be limited, and the line width of the first power signal line may be greatly thinned. At this point, the voltage uniformity of the first power signal line in the display panel may only reach 83%. It may be seen that if the solution of reducing the film layer is directly adopted, the voltage drop of the first power signal line may be greatly reduced. In such way, the voltage uniformity of the first power signal line may become poor, which may result in uneven display and affect display quality. That is, saving fabrication cost and ensuring display quality cannot be achieved at the same time. In embodiments of the present disclosure, the first conductive line 20A in the second metal layer M2 and the second conductive line 20B in the third metal layer M3 in a same first power signal line 20 may be configured to be electrically connected to each other, which may reduce the impedance of the same first power signal line 20 and prevent reduced voltage uniformity of the first power signal line 20 due to excessive impedance of the first power signal line 20. The structure of the first power line 20 provided in the present disclosure may increase the voltage uniformity of the first power signal line 10 in the display panel 000 to 88%, which may have voltage uniformity basically same as or adjacent to the voltage uniformity of the first connection line made by disposing another film layer in the panel and satisfy display effect requirement. Therefore, in one embodiment, the display uniformity of the display panel 000 may be greatly improved by improving the voltage uniformity of the first power signal line 20, thereby ensuring the display quality while saving process steps and fabrication cost.

It should be noted that the drawings in one embodiment only illustrate the structure of the display panel. During an implementation, the display panel 000 may further include other structures capable of realizing the display function, such as scan driving circuits and peripheral wires in the non-display region NA and the like, which may not be described in detail in one embodiment. The structure of the pixel circuit included in the sub-pixel P may not be limited in one embodiment, which may refer to the structure of the display panel in the existing technology for details.

It should be further noted that FIG. 3 of one embodiment only illustrates a part of the film layer structure of the display panel 000. During an implementation, the display panel 000 may further include other film layers, such as a light-emitting functional layer, a pixel definition layer, a cathode layer, an encapsulation layer and the like, which may not be described in detail herein. Other film layers may be understood with reference to the film layer structure of organic light-emitting diodes in the existing technology.

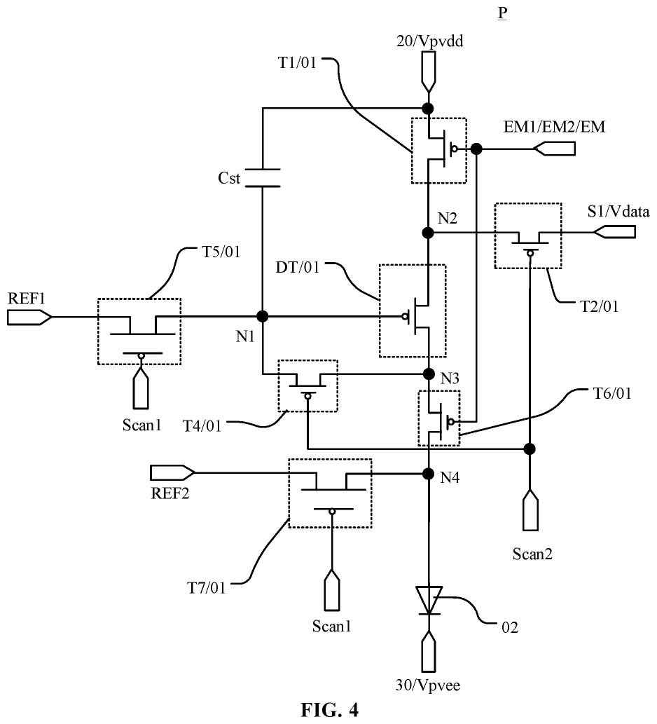

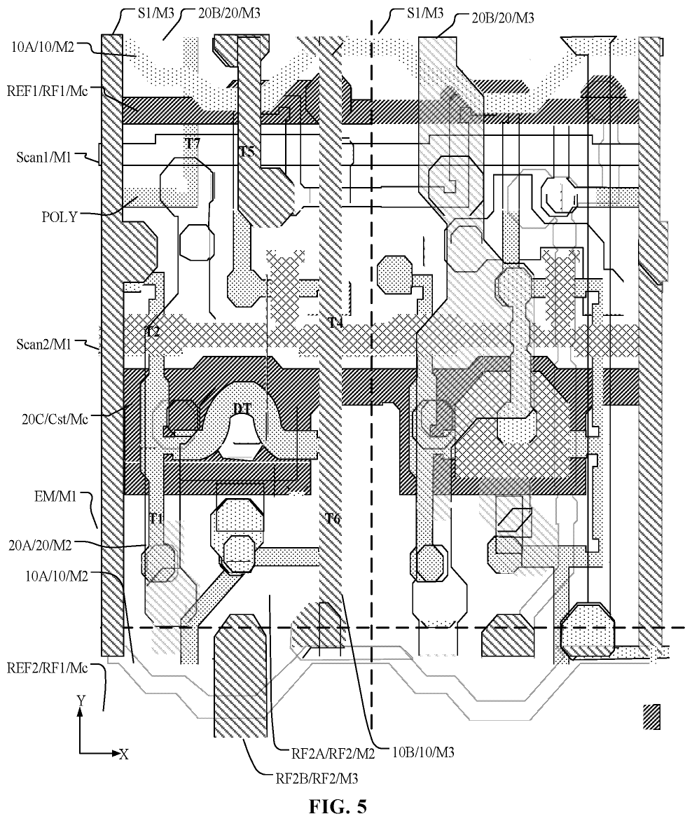

Optionally, referring to FIGS. 1-3 and 4-5, FIG. 4 illustrates a structural schematic of electrical connection between the pixel circuit and the light-emitting element in the display panel according to various embodiments of the present disclosure; and FIG. 5 illustrates a circuit layout when the pixel circuit structure in FIG. 4 is formed on the substrate of the display panel. It may be understood that, in order to clearly illustrate the structure of one embodiment, transparency filling is performed in FIG. 5. In one embodiment, the display panel 000 may include the plurality of sub-pixels P, and the sub-pixel P may include a pixel circuit 01 and a light-emitting element 02 which are electrically connected to each other. The light-emitting element 02 may be an organic light-emitting diode. The pixel circuit 01 may include a first transistor T1, a second transistor T2, a driving transistor DT, a fourth transistor T4, a fifth transistor T5, a sixth transistor T6, a seventh transistor T7, and a storage capacitor Cst. The gate electrode of the driving transistor DT may be connected to the first electrode of the fifth transistor T5, the second electrode of the fifth transistor T5 may be connected to the first reset signal line REF1, and the gate electrode of the fifth transistor T5 may be connected to the first scan signal line Scan1.

The first electrode of the driving transistor DT may be connected to the first electrode of the first transistor T1, the second electrode of the first transistor T1 may be connected to the first power supply signal line 20, and the gate electrode of the first transistor T1 may be connected to the first light-emitting control signal line EM1.

The first electrode of the driving transistor DT may be also connected to the first electrode of the second transistor T2, the second electrode of the second transistor T2 may be connected to a data line (e.g., the first data line S1), and the gate electrode of the second transistor T2 may be connected to the second scanning signal line Scan2.

The second electrode of the driving transistor DT may be connected to the first electrode of the sixth transistor T6, the second electrode of the sixth transistor T6 may be connected to an anode of the light-emitting element 02, a cathode of the light-emitting element 02 may be connected to the second power supply signal line 30, and the gate electrode of the sixth transistor T6 may be connected to the second light-emitting control signal line EM2. Optionally, the first light-emitting control signal line EM1 and the second light-emitting control signal line EM2 may share a same light-emitting control signal line. When the gate electrode of the first transistor T1 and the gate electrode of the sixth transistor T6 jointly respond to a light-emitting control signal provided by the light-emitting control signal line EM, the first transistor T1 and the sixth transistor T6 may be in a conduction (e.g., on) state.

The first electrode of the seventh transistor T7 may be connected to the second reset signal line REF2, the second electrode of the seventh transistor T7 may be connected to the anode of the light-emitting element 02, and the gate electrode of the seventh transistor T7 may be connected to the first scanning signal line Scan1. That is, when the gate electrode of the fifth transistor T5 and the gate electrode of the seventh transistor T7 jointly respond to the first scan signal Scan1, the fifth transistor T5 and the seventh transistor T7 may be in a conduction (e.g., on) state. Optionally, the first reset signal line REF1 and the second reset signal line REF2 may provide different reset voltage signals; or the first reset signal line REF1 and the second reset signal line REF2 may jointly provide a same reset voltage signal. In the drawings of one embodiment, the first reset signal line REF1 and the second reset signal line REF2 may provide different reset voltage signals as an example for illustration.

The first electrode of the fourth transistor T4 may be connected to the gate electrode of the driving transistor DT, the second electrode of the fourth transistor T4 may be connected to the second electrode of the driving transistor DT, and the gate electrode of the fourth transistor T4 may be connected to the second scanning signal line Scan2. That is, the gate electrode of the fourth transistor T4 and the gate electrode of the second transistor T2 may be jointly connected to the second scanning signal line Scan2. When the gate electrode of the fourth transistor T4 and the gate electrode of the second transistor T2 jointly respond to the scan drive signal provided by the second scan signal line Scan2, the fourth transistor T4 and the second transistor T2 may be in a conduction (e.g., on) state.

One terminal of the storage capacitor Cst may be connected to the first power supply signal line 20, and another terminal of the storage capacitor Cst may be connected to the gate electrode of the driving transistor DT. The storage capacitor Cst may be configured to stabilize the potential of the gate electrode of the driving transistor DT, which may be beneficial for maintaining the driving transistor DT to be in conduction.

In one embodiment, it describes that the pixel circuit 01 in the display panel 000 may include a circuit connection structure; and the pixel circuit 01 may include a plurality of transistors and a storage capacitor Cst, where one transistor may be the driving transistor DT, and remaining transistors may be switching transistors. Taking the electrical connection structure of the pixel circuit 01 and the light-emitting element 02 shown in FIG. 4 of one embodiment as an example, the position at the gate electrode of the driving transistor DT represents the first node N1, and the position at the first electrode of the driving transistor DT represents the second node N2, the position at the second electrode of the driving transistor DT represents the third node N3, and the position at the anode of the light-emitting element 02 represents the fourth node N4. The working principle of such sub-pixel P is described hereinafter.

In an initial reset stage, the fifth transistor T5 and the seventh transistor T7 may be in conduction, and remaining transistors may be in cut-off. The potential of the first node N1 may be the first reset signal provided by the first reset signal line REF1, the potential of the fourth node N4 may be the second reset signal provided by the second reset signal line REF2, and the gate electrode of the driving transistor DT and the anode of the light emitting element 02 may be reset.

During a data write and threshold capture stage, the second transistor T2, the fourth transistor T4, and the driving transistor DT may be in conduction, and remaining transistors may be in cut-off. The potential of the second node N2 may be a data voltage signal Vdata provided by the first data line S1, and the potential of the first node N1 and the third node N3 may be Vdata−|Vth|, where Vth is the threshold voltage of the driving transistor DT.

In a light-emitting stage, the first transistor T1, the sixth transistor T6, and the driving transistor DT may be in conduction, and remaining transistors may be in cut-off. The positive power signal Vpvdd provided by the first power signal line 20 may be transmitted to the driving transistor DT, and the driving transistor DT may generate a driving current to drive the light-emitting element 02 to emit light. The potential of the second node N2 may be the positive power supply signal Vpvdd, the potential of the first node N1 may be Vdata−|Vth|, and the potential of the third node N3 may be Vpvee+Voled. Vpvee is a negative power signal provided by the second power signal line 30, which is a negative potential, and Voled is corresponding voltage on the light-emitting element 02. Therefore, the light-emitting current may be computed using Id=k(Vgs−|Vth|)2=k(Vpvdd−Vdata−|Vth|)2, where a constant k is related to the performance of the driving transistor DT itself, and Vgs is a voltage difference between a gate voltage and a source voltage of the driving transistor.

It may be understood that, in one embodiment, it only illustrates the electrical connection structure that the sub-pixel P includes the pixel circuit 01 and the light-emitting element 02 when the display panel 000 is an organic light-emitting diode display panel. During an implementation, the electrical connection structure that the sub-pixel P includes the pixel circuit 01 and the light-emitting element 02 may include, but may not be limited to, such structure, and may also be other implementation structure, which may not be described in detail in one embodiment and refer to the structure of the pixel circuit in the existing technology.

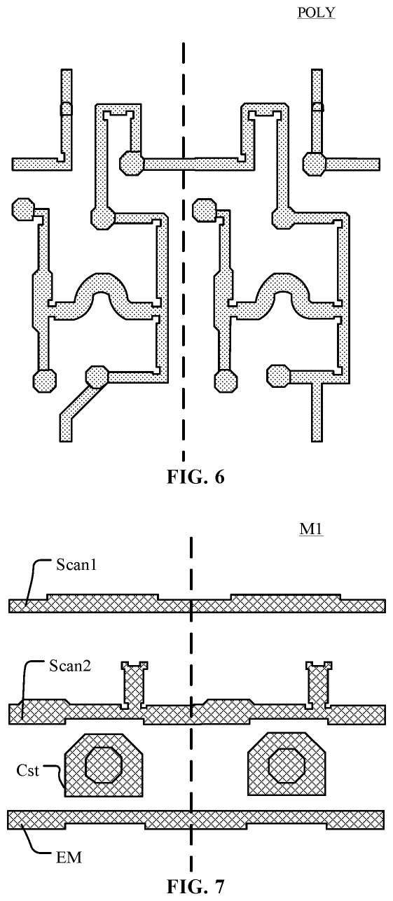

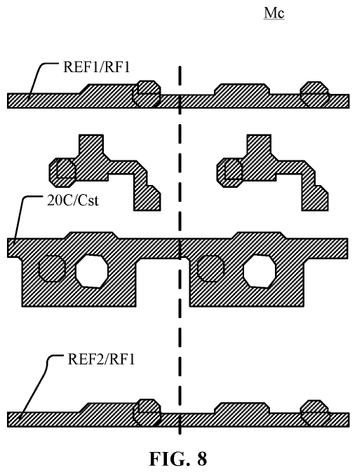

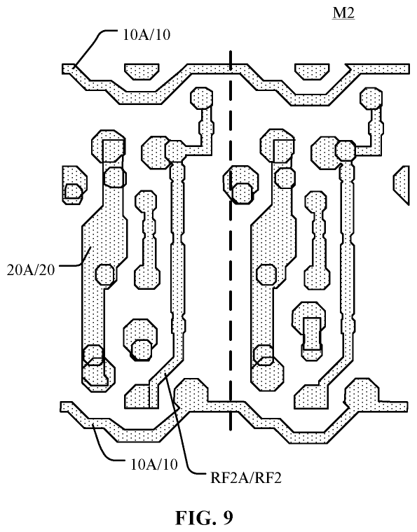

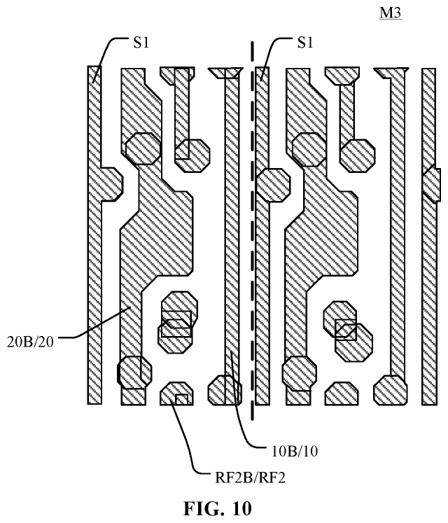

When being fabricated on the substrate 00 included in the display panel 000, above exemplary pixel circuit 01 may be schematically shown as the circuit layout of FIG. 5. The film layer structure of the display panel 000 may at least include the semiconductive layer POLY, the first metal layer M1, the capacitive metal layer Mc, the second metal layer M2, and the third metal layer M3. Referring to FIGS. 6-10, FIG. 6 illustrates a structural schematic of the semiconductive layer in FIG. 5; FIG. 7 illustrates a structural schematic of the first metal layer in FIG. 5; FIG. 8 illustrates a structural schematic of the capacitor metal layer in FIG. 5; FIG. 9 illustrates a structural schematic of the second metal layer in FIG. 5; and FIG. 10 illustrates a structural schematic of the third metal layer in FIG. 5. FIGS. 6-10 may be sequentially overlapped to form the layout of the pixel circuit illustrated in FIG. 5. It may be understood that the pixel circuit including two sub-pixels may be used as an example for illustration in FIG. 5. The active portion of the transistor in the pixel circuit may be in the semiconductive layer POLY, and the gate electrode of the transistor in the pixel circuit may be in the first metal layer M1. The first scanning signal line Scan1, the second scanning signal line Scan2, and the light-emitting control signal line EM may be in the first metal layer M1. Two terminals of the storage capacitor Cst included in the pixel circuit may be in the first metal layer M1 and the capacitor metal layer Mc respectively; and the first reset signal line REF1 and the second reset signal line REF2 may be in the capacitor metal layer Mc. The source and drain electrode of the transistor in the pixel circuit may be in the second metal layer M2, the first conductive line 20A of the first power signal line 20 may be in the second metal layer M2, and the first sub-segment 10A of the first connection line 10 may be in the second metal layer M2. The first data line S1 and the second data line S2 may be in the third metal layer M3, the second conductive line 20B of the first power signal line 20 may be in the third metal layer M3, and the second sub-segment 10B of the first connection line 10 may be in the third metal layer M3.

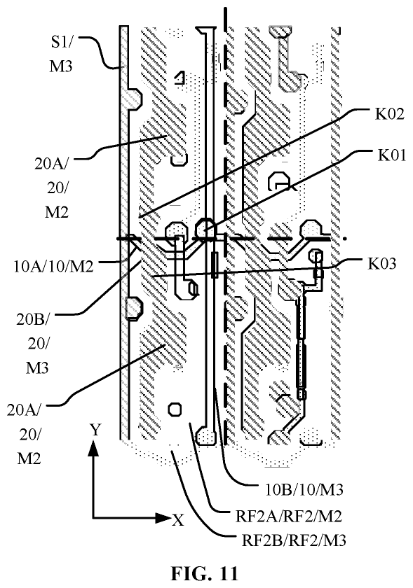

Referring to FIG. 11, FIG. 11 illustrates a structural schematic of two rows of exemplary pixel circuits after the second metal layer and the third metal layer are overlapped in FIG. 5. It may be understood that in order to clearly illustrate the structure of one embodiment, transparency filling is performed in FIG. 11. In one embodiment, the first data line S1 in the third metal layer M3 may be electrically connected to the first sub-segment 10A of the first connection line 10 in the second metal layer M2 through at least one via (not shown in FIG. 11); and the first sub-segment 10A of the first connection line 10 in the second metal layer M2 may be electrically connected to the second sub-segment 10B of the first connection line 10 in the third metal layer M3 through at least one via (K01 shown in FIG. 11). In such way, it realizes that the second metal layer M2 and the third metal layer M3 included in the display panel 000 may be configured to fabricate the first connection line 10, which may ensure narrow frame of the display panel 000 while avoiding disposing additional film layers to increase panel thickness and process steps, thereby improving process efficiency and saving fabrication cost.

In one embodiment, the extension directions of the first conductive line 20A of the first power signal line 20 in the second metal layer M2 and the second conductive line 20B of the first power signal line 20 in the third metal layer M3 may be same; and both the first conductive line 20A and the second conductive line 20B may extend along the first direction Y. In addition, the first conductive line 20A and the second conductive line 20B of a same first power signal line 20 may be overlapped with each other along the direction perpendicular to the plane of the substrate 00. The first conductive line 20A of the first power signal line 20 in the second metal layer M2 may be electrically connected to the second conductive line 20B of the first power signal line 20 in the third metal layer M3 through at least one via (K02 shown in FIG. 11). In such way, the second conductive line 20B of the first power signal line 20 in the third metal layer M3 may avoid the first sub-segment 10A of the first connection line 10 in the second metal layer M2 extending along the first direction X. Then, after avoiding the first sub-segment 10A of the first connection line 10 in the second metal layer M2 extending along the first direction X, the first power signal line 20 may be changed back to the second metal layer M2. That is, another end of the second conductive line 20B of the first power signal line 20 in the third metal layer M3 may be electrically connected to the first conductive line 20A of the first power signal line 20 in the second metal layer M2 on another side of the first sub-segment 10A through at least one via (K03 shown in FIG. 11). One first power signal line 20 may be configured as the first conductive line 20A and the second conductive line 20B which are overlapped and electrically connected to each other, which may be beneficial for reducing the impedance of the first power signal line 20, such that the line width of the first power signal line 20 may be effectively ensured. In such way, it may prevent reduced voltage uniformity of the first power signal line 20 due to the impedance increase of the first power signal line 20 to affect the display uniformity, thereby improving the display uniformity of the display panel 000. In addition, along the direction perpendicular to the plane of the display panel 000, the first conductive line 20A and the second conductive line 20B disposed in different layers in a same first power signal line 20 may be at least partially overlapped with each other, which may effectively improve the problem of relatively large impedance caused by relatively thin width of the first power signal line 20 due to space limitation. Furthermore, the width of the first power signal line 20 itself may be appropriately increased by overlapping the first conductive line 20A with the second conductive line 20B, which may further reduce the impedance of the first power signal line 20 itself, thereby being beneficial for further improving the display quality.

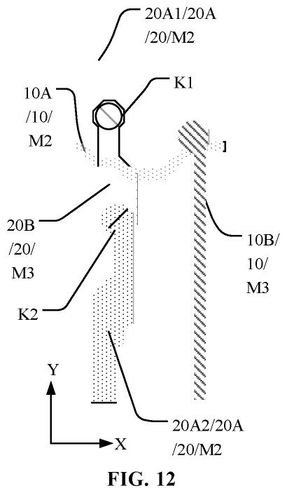

In some optional embodiments, referring to FIGS. 1, 2, 11 and 12, FIG. 12 illustrates a structural schematic of the first power signal line and the first connection line in FIG. 11. It may be understood that, in order to clearly illustrate the structure of one embodiment, transparency filling is performed in FIG. 12. In one embodiment, the first conductive line 20A may include a first portion 20A1 and a second portion 20A2 which are disconnected from each other; and along the first direction Y, the first portion 20A1 and the second portion 20A2 may be respectively on two opposite sides of the first sub-segment 10A.

In one embodiment, it describes that the first sub-segment 10A of the first connection line 10 and the first conductive line 20A of the first power signal line 20 may be disposed in a same layer (e.g., both in the second metal layer M2); the first conductive line 20A and the second conductive line 20B of the first power signal line 20 may both extend along the first direction Y; after the first sub-segment 10A of the first connection line 10 is connected to the first data line S1, the first sub-segment 10A of the first connection line 10 may need to extend to the second display region AA2 along the second direction X. Therefore, at least a part of the first sub-segment 10A of the first connection line 10 may need to extend along the second direction X to be adjacent to the second display region AA2. When the first conductive line 20A of the first power signal line 20 extends along the first direction Y, the first conductive line 20A may need to avoid the first sub-segment 10A of the first connection line 10 in a same layer. In one embodiment, the first conductive line 20A extending along the first direction Y may include the first portion 20A1 and the second portion 20A2 which are disconnected from each other; and the first portion 20A1 and the second portion 20A2 may be respectively on two opposite sides of the first sub-segment 10A. Therefore, the first sub-segment 10A in a same layer as the first conductive line 20A may be avoided by the first portion 20A1 and the second portion 20A2 which are disconnected from each other. Furthermore, the first conductive line 20A of the second metal layer M2 and the second conductive line 20B of the third metal layer M3 may be electrically connected to each other, such that the impedance of the first power signal line 20 may be reduced, and the short circuit problem between the first conductive line 20A and the first sub-segment 10A in a same layer may be avoided to ensure fabrication yield.

Optionally, the first portion 20A1 of the first conductive line 20A may be electrically connected to the second conductive line 20B through the first via K1, and the second portion 20A2 may be electrically connected to the second conductive line 20B through the second via K2; and along the first direction Y, the first via K1 and the second via K2 may be respectively on two opposite sides of the first sub-segment 10A.

In one embodiment, it describes that the first conductive line 20A and the second conductive line 20B in different layers may be electrically connected through vias. For example, the first conductive line 20A may include the first portion 20A1 and the second portion 20A2 which are disconnected from each other. Along the first direction Y, the first portion 20A1 on one side of the first sub-segment 10A may be electrically connected to the second conductive line 20B of the third metal layer M3 through the first via K1, such that the second conductive line 20B in the third metal layer M3 may cross the first sub-segment 10A of the first connection line 10. Next, on another side of the first sub-segment 10A, the second portion 20A1 of the first conductive line 20A may be electrically connected to the second conductive line 20B of the third metal layer M3 through the second via K2. The electrical connection between the first portion 20A1 of the second metal layer M2 on one side of the first sub-segment 10A, the second conductive line 20B in the third metal layer M3 crossing the first sub-segment 10A, and the second portion 20A2 of the second metal layer M2 on another side of the first sub-segment 10A may be realized. It may also satisfy that the first portion 20A1 and the second conductive line 20B may be at least partially overlapped with each other; and the second portion 20A2 and the second conductive line 20B may be at least partially overlapped with each other. While reducing the impedance of the first power signal line 20, the first portion 20A1 and the second portion 20A2 which are disconnected from each other may also avoid the short circuit problem of the first conductive line 20A and the first sub-segment 10A in a same layer, thereby ensuring the fabrication yield.

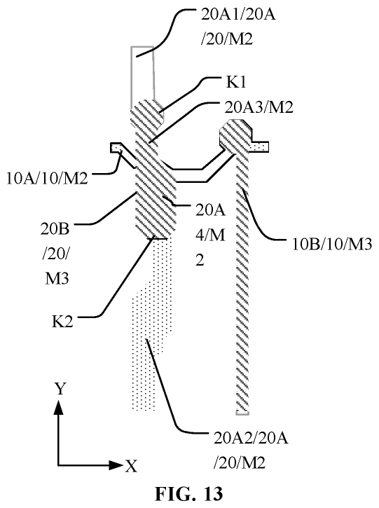

Furthermore, optionally, referring to FIGS. 1, 2, 11 and 13, FIG. 13 illustrates another structural schematic of the first power signal line and the first connection line in FIG. 11. It may be understood that in order to clearly illustrate the structure in one embodiment, transparency filling is performed in FIG. 13. In one embodiment, the first portion 20A1 may be connected to the first extension segment 20A3; the second portion 20A2 may be connected to the second extension segment 20A4; and the first extension segment 20A3 and the second extension segment 20A4 may be both disposed in a same layer as the first conductive line 20A.

Along the first direction Y, the first extension segment 20A3 and the second extension segment 20A4 may be respectively on two opposite sides of the first sub-segment 10A; the first extension segment 20A3 may be on the side of the first via K1 facing the first sub-segment 10A; and the second extension segment 20A4 may be on the side of the second via K2 facing the first sub-segment 10A.

In one embodiment, it describes that the first conductive line 20A in the second metal layer M2 may include the first portion 20A1 and a second portion 20A2 which are disconnected from each other. The first portion 20A1 may be connected to the first extension segment 20A3 in a same layer as the first portion 20A1, and the second portion 20A2 may be connected to the second extension segment 20A4 in a same layer as the second portion 20A2. Along the first direction Y, the first extension segment 20A3 and the second extension segment 20A4 may be respectively on two opposite sides of the first sub-segment 10A, and the first extension segment 20A3 may be on the side of the first via K1 facing the first sub-segment 10A. That is, the first portion 20A1 may extend along the direction adjacent to the first sub-segment 10A to further form the first extension segment 20A3, and the second portion 20A2 may extend along the direction adjacent to the first sub-segment 10A to further form the second extension segment 20A4. Therefore, the first conductive line 20A in the second metal layer M2 may be further extended through disposing the first extension segment 20A3 and the second extension segment 20A4. Furthermore, the overlapping area of the first conductive line 20A and the second conductive line 20B may be increased by increasing the area of the first conductive line 20A. After the first conductive line 20A and the second conductive line 20B in different layers are electrically connected to each other, the overlapping area of the first conductive line 20A and the second conductive line 20B may increase, which is equivalent to thickening the first power signal line 20, thereby being beneficial for further reducing overall impedance of the first power signal line 20 and improving the display quality of the display panel 000.

It may be understood that, in one embodiment, the extension length of the first extension segment 20A3 and the second extension segment 20A4 along the first direction Y may not be limited, which may only need to satisfy that overlapping is not between the first sub-segment 10A and each of the first extension segment 20A3 and the second extension segment 20A4, and the short circuit between the first extension segment 20A3 and the first sub-segment 10A in a same layer as the first extension segment 20A3, and between the second extension segment 20A4 and the first subsegment 10A in a same layer as the second extension segment 20A4 may be avoided.

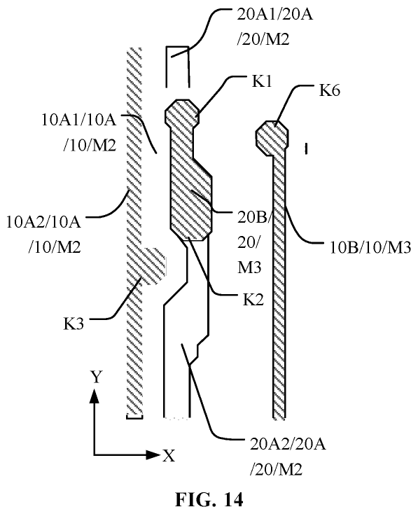

In some optional embodiments, referring to FIGS. 1, 2, 11 and 14, FIG. 14 illustrates a structural schematic of the first data line, the first power signal line and the first connection line in FIG. 11. It may be understood that in order to clearly illustrate the structure in one embodiment, transparency filling is performed in FIG. 14. In one embodiment, at least a part of the first sub-segment 10A may extend along the second direction X, and the second sub-segment 10B may extend along the first direction Y, where the first direction Y may intersect the second direction X. It may be understood that in one embodiment, the first direction Y and the second direction X may be perpendicular to each other as an example for illustration.

Optionally, the first sub-segment 10A may include the first sub-portion 10A1 extending along the second direction X and the second sub-portion 10A2 extending along the first direction Y.

Along the direction perpendicular to the plane of the display panel 000, the second sub-portion 10A2 may be overlapped with the first data line S1, and the second sub-portion 10A2 and the first data line S1 may be electrically connected through the third via K3.

In one embodiment, it describes that when the first connection line 10 is fabricated using the film layer included in the display panel 000 itself, the first sub-segment 10A of the first connection line 10 may be in the second metal layer M2, and the second sub-segment 10B may be in the third metal layer M3. Optionally, the first sub-segment 10A and the second sub-segment 10B of the same first connection line 10 may be electrically connected through the sixth via K6. In one embodiment, it configures that at least a part of the first sub-segment 10A extends along the second direction X. In such way, through at least a part of the first sub-segment 10A extending along the second direction X, the effect of the first connection line 10 extend toing the second display region AA2 may be realized, which may be beneficial for achieving narrow frame of the display panel 000 through the first connection line 10 in the display region AA. The second sub-segment 10B of the first connection line 10 may extend along the first direction Y, and further extend to the edge on one side of the display region AA adjacent to the non-display region NA through the extension of the second sub-segment 10B. It may be understood that, in drawings of one embodiment, it only illustrates that the first connection line 10 including the first sub-segment 10A and the second sub-segment 10B may be taken as an example to illustrate the bending shape of the first connection line 10. During an implementation, the first connection line 10 may further include multiple first sub-segments 10A and multiple second sub-segments 10B which are sequentially connected to form multiple bent structures, which may not be limited in one embodiment.

In one embodiment, it configures that the first sub-segment 10A may include the first sub-portion 10A1 extending along the second direction X and the second sub-portion 10A2 extending along the first direction Y. That is, the first sub-segment 10A in the second metal layer M2 may not only include the first sub-portion 10A1 extending along the second direction X, but further include the second sub-portion 10A2 extending along the first direction Y. Furthermore, the second sub-portion 10A2 and the first data line S1 may be overlapped with each other along the direction perpendicular to the plane of the display panel 000. The second sub-portion 10A2 in the second metal layer M2 and the first data line S1 in the third metal layer M3 may be electrically connected through the third via K3. The position of the third via K3 connected to the first data line S1 may be more flexible by disposing the second sub-portion 10A2 along a same extension direction as the first data line S1. The third via K3 electrically connecting the first data line S1 and the first sub-segment 10A may avoid the structures of certain pixel circuits, and the formation of the third via K3 may be prevented from affecting the layout of the pixel circuit itself, thereby being beneficial for improving display quality and fabrication yield.

It may be understood that the signal lines described in above embodiments extending along the first direction Y or the second direction X may indicate that overall extension direction of the signal line may be along the first direction Y or the second direction X. For example, the first sub-portion 10A1 of the first sub-segment 10A of the first connection line 10 extending along the second direction X may only indicate that overall extension direction of the first sub-portion 10A1 may be the second direction X, and the first sub-portion 10A1 may have multiple bending structures, which may flexibly configure the shape of the first sub-portion 10A1, avoid certain structures of the pixel circuit and improve fabrication yield.

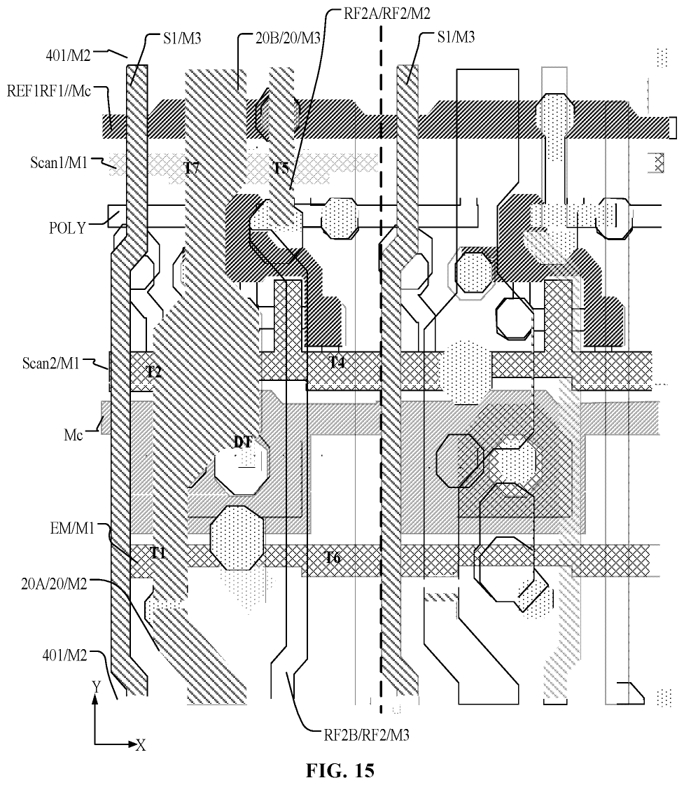

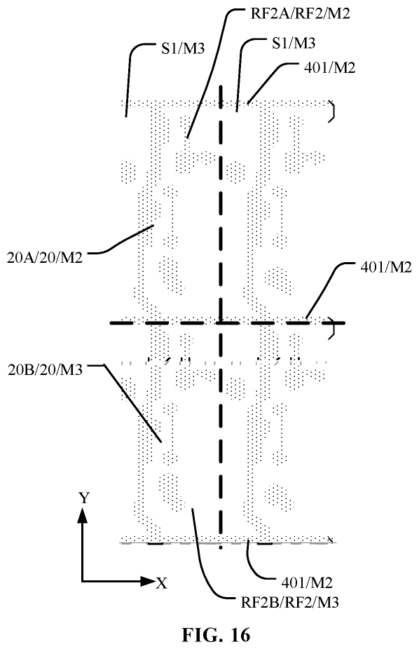

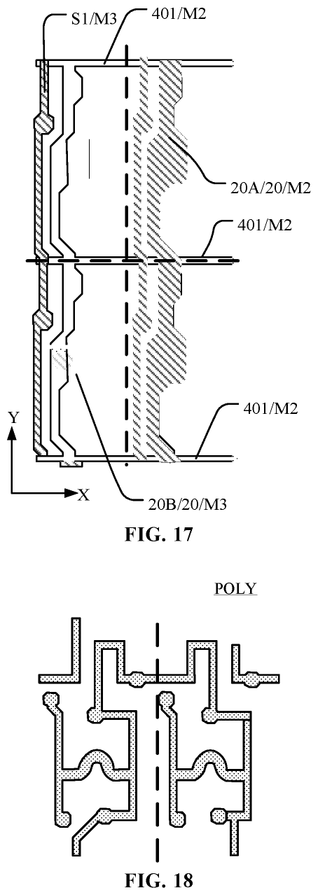

In some optional embodiments, referring to FIGS. 1-2, 4 and 15-17, FIG. 15 illustrates another circuit layout when the pixel circuit structure in FIG. 4 is formed on the substrate of the display panel; FIG. 16 illustrates a structural schematic of two rows of exemplary pixel circuits after the second metal layer and the third metal layer are overlapped in FIG. 15; and FIG. 17 illustrates a structural schematic of the first data line, the first power signal line and the first compensation signal line in FIG. 16. It may be understood that in order to clearly illustrate the structure in one embodiment, transparency filling is performed in FIGS. 15-17. In one embodiment, the display panel 000 may further include a plurality of first compensation signal lines 401. The first compensation signal line 401 may be disposed in a same layer as the first sub-segment 10A. The first compensation signal line 401 may extend along a same direction as the first sub-segment 10A. The first compensation signal line 401 and the first sub-segment 10A may be insulated from each other. The first compensation signal line 401 may be electrically connected to the first power signal line 20.

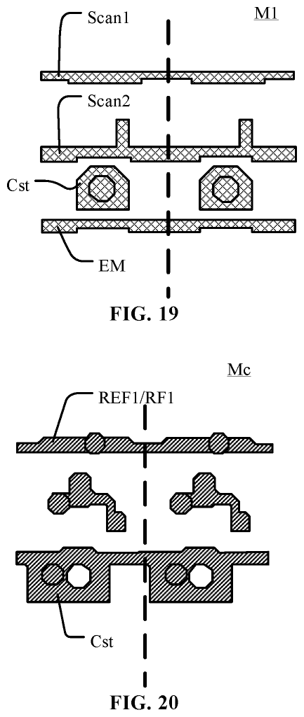

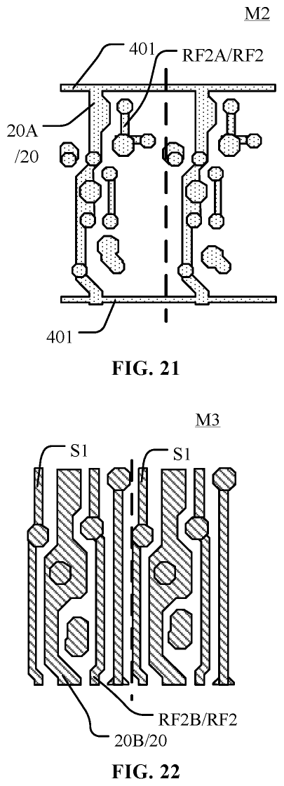

In one embodiment, it describes that the display panel 000 may further include the plurality of first compensation signal lines 401. The first compensation signal line 401 may also be fabricated using the film layer included in the display panel 000 itself, such as using the second metal layer M2 where the first sub-segment 10A of the first connection line 10 is located. When the first compensation signal line 401 is disposed in a same layer as the first sub-segment 10A of the first connection line 10, the region where the first connection line 10 is located may be avoided. That is, the region in the display region AA where the first connection line 10 needs to be connected to the first data line S1 is defined as a FIAA region, such that the display region AA without need to dispose the first connection line 10 is defined as a non-FIAA region. FIG. 15 of one embodiment is the layout of the pixel circuit in the non-FIAA region, such that the first connection line 10 is not included in FIG. 15. Referring to FIGS. 18-22, FIG. 18 illustrates a structural schematic of the semiconductive layer in FIG. 15; FIG. 19 illustrates a structural schematic of the first metal layer in FIG. 15; FIG. 20 illustrates a structural schematic of the capacitor metal layer in FIG. 15; FIG. 21 illustrates a structural schematic of the second metal layer in FIG. 15; and FIG. 22 illustrates a structural schematic of the third metal layer in FIG. 15. It may be understood that the pixel circuit including two sub-pixels is taken as an example for illustration in FIG. 15. In one embodiment, the first compensation signal line 401 may be disposed in the second metal layer M2, such that the extension directions of the first compensation signal line 401 and the first sub-segment 10A may be same. Optionally, the first compensation signal line 401 and the first sub-portion 10A1 of the first sub-segment 10A may extend along a same direction (e.g., both extend along the second direction X). However, the first compensation signal line 401 and the first sub-segment 10A may be insulated from each other. The first compensation signal line 401 may be not connected to the first sub-segment 10A of the first connection line 10 but may be electrically connected to the first power signal line 20. In such way, the second metal layer M2 included in the display panel 000 itself may be configured to fabricate the first compensation signal line 401 electrically connected to the first power signal line 20. The space of the second metal layer M2 may be fully used, such that the first compensation signal line 401 extending along the second direction X and the first conductive line 20A of the first power signal line 20 extending along the first direction Y may be connected to each other to form a grid-like structure, which may be beneficial for further reducing the impedance of the first power signal line 20 and desirable ensuring overall display effect of the display panel 000.

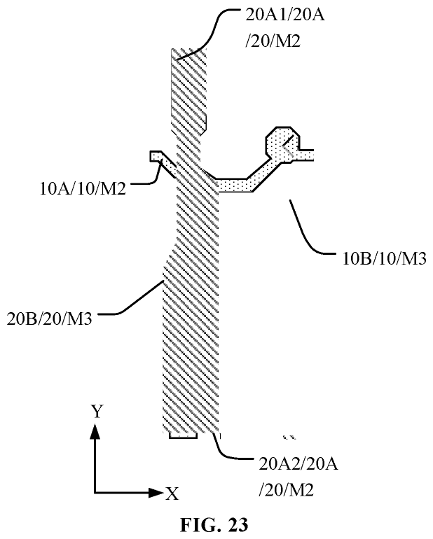

Optionally, referring to FIGS. 1, 2, 4, 5, 11, 15, 17 and 23, FIG. 23 illustrates another structural schematic of the first power signal line and the first connection line in FIG. 11. It may be understood that in order to clearly illustrate the structure in one embodiment, transparency filling is performed in FIG. 23. When the first conductive line 20A and the second conductive line 20B of the first power signal line 20 are overlapped and electrically connected with each other, the area of the second conductive line 20B in the third metal layer M3 may be expanded as possible. The length of the second conductive line 20B along the first direction Y (e.g., the second conductive line 20B in the non-FIAA region in FIG. 17, or the second conductive line 20B in the FIAA region in FIG. 23) may be increased as possible only without affecting other conductive structures. In such way, the overlapping area of the first conductive line 20A in the second metal layer M2 and the second conductive line 20B in the third metal layer M3 may be as large as possible, which may be beneficial for desirably reducing overall impedance of the first power signal line 20.

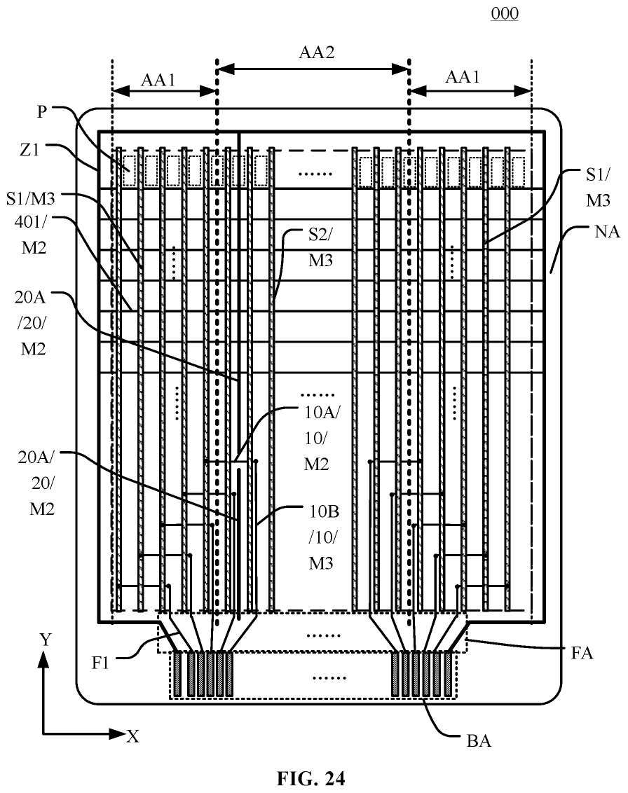

Optionally, referring to FIG. 24, FIG. 24 illustrates another planar structural schematic of the display panel according to various embodiments of the present disclosure. The display panel 000 may include the non-display region NA. In the non-display region NA, the first compensation signal line 401 may be connected to the first power signal line 20.

The first power signal line 20 providing a positive power signal in the display panel 000 may be disposed in the display region AA and subsequently need to be connected to a positive power bus Z1 in the non-display region NA. Through electrical connection between the driver chip or flexible circuit board subsequently bound to the display panel 000 and the positive power bus Z1, the positive power signal port of the driver chip or the flexible circuit board may provide a positive power signal to the first power signal line 20 in the display region AA through the positive power bus Z1 in the non-display region NA. In one embodiment, the first compensation signal line 401 electrically connected to the first power signal line 20 may be fabricated using the second metal layer M2 included in the display panel 000 itself, such that the first compensation signal line 401 extending along the second direction X and the first conductive line 20A of the first power signal line 20 extending along the first direction Y may be connected to each other to form a grid-like structure, which may sufficiently use the space of the second metal layer M2. When further reducing the impedance of the first power signal line 20, the first compensation signal line 401 may be configured to be electrically connected to the first power signal line 20 within the non-display region NA. Optionally, the first compensation signal line 401 may be connected to the positive power bus Z1 in the non-display region NA through a via in the non-display region NA, thereby realizing the electrical connection between the first compensation signal line 401 and the first power signal line 20. In one embodiment, the first compensation signal line 401 may be configured to be connected to the positive power bus Z1 in the non-display region NA through a via in the non-display region NA. In such way, the vias may be in the non-display region NA, which may be beneficial for reducing the number of vias in the display region AA as possible, preventing excessive number of vias in the display region AA from affecting the display uniformity and further improving display quality.

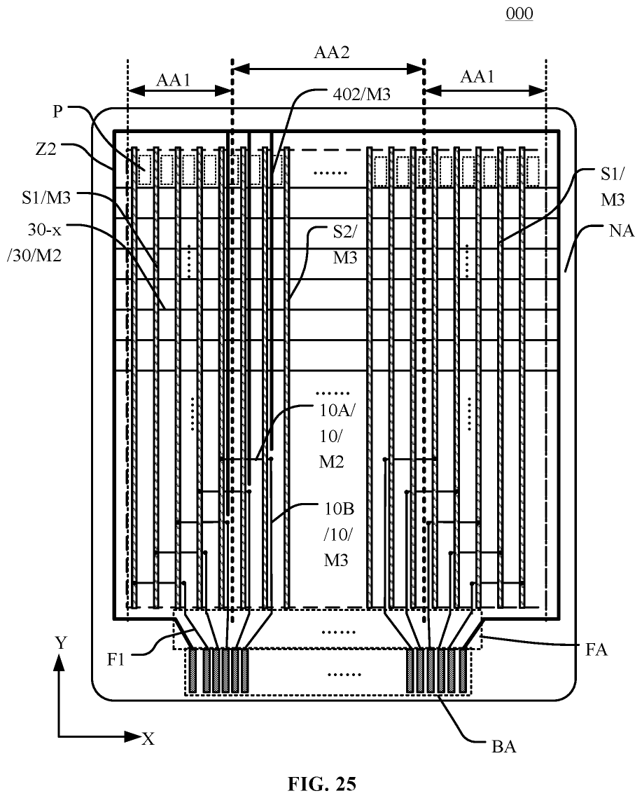

In some optional embodiments, referring to FIG. 25, FIG. 25 illustrates another planar structural schematic of the display panel according to various embodiments of the present disclosure. In one embodiment, the display panel 000 may further include a plurality of second compensation signal lines 402. The second compensation signal line 402 may be disposed in a same layer as the second sub-segment 10B. The second compensation signal line 402 may extend along a same direction as the second sub-segment 10B. The second compensation signal line 402 and the second sub-segment 10B may be insulated from each other. The display panel 000 may further include the second power signal line 30; and the second compensation signal line 402 may be electrically connected to the second power signal line 30.

In one embodiment, it describes that the display panel 000 may further include the second power signal line 30. The second power signal line 30 may be configured to provide a negative power signal. The second power signal line 30 may be fabricated using the second metal layer M2 in the display panel 000. Optionally, the second power signal line 30 may include a horizontal second power signal line 30-x in the second metal layer M2 extending along the second direction X, which may not be limited in one embodiment. In one embodiment, the second compensation signal line 402 may be disposed in the third metal layer M3, such that the extension directions of the second compensation signal line 402 and the second sub-segment 10B of the first connection line 10 may be same. Optionally, the extension directions of the second compensation signal line 402 and the second sub-segment 10B may be same (e.g., both extend along the first direction Y). However, the second compensation signal line 402 and the second sub-segment 10B may be insulated from each other. The second compensation signal line 402 may not be connected to the second sub-segment 10B of the first connection line 10 but may be electrically connected to the second power signal line 30. In such way, the third metal layer M3 included in the display panel 000 itself may be configured to fabricate the second compensation signal line 402 electrically connected to the second power signal line 30. The space of the third metal layer M3 may be sufficiently used, such that the horizontal second power signal line 30-x extending along the second direction X and the second compensation signal line 402, which extends along the first direction Y and is disposed in a same layer as the second power signal line 30-x, may be connected to each other to form a grid-like structure, which may be beneficial for further reducing the impedance of the second power signal line 30 and desirably ensuring overall display effect of the display panel 000.

Optionally, as shown in FIG. 25, the display panel 000 may include the non-display region NA. In the non-display region NA, the second compensation signal line 402 and the second power signal line 30 may be connected through a via. The second power signal line 30 providing a negative power signal in the display panel 000 may be disposed in the display region AA and may need to be subsequently connected to a negative power bus Z2 in the non-display region NA. Through the electrical connection between the driver chip or flexible circuit board subsequently bound to the display panel 000 and the negative power bus Z2, the negative power signal port of the driver chip or the flexible circuit board may provide a negative power signal to the second power signal line 30 of the display region AA through the negative power bus Z2 of the non-display region NA. In one embodiment, the second compensation signal line 402 electrically connected to the second power signal line 30 may be fabricated using the third metal layer M3 included in the display panel 000 itself. In such way, the horizontal second power signal line 30-x extending along the second direction X and the second compensation signal line 402, which extends along the first direction Y and is disposed in a same layer as the second power signal line 30-x, may be connected to each other to form a grid-like structure, which may sufficiently use the space of the third metal layer M3. When further reducing the impedance of the second power signal line 30, the second compensation signal line 402 may be configured to be electrically connected to the second power signal line 30 within the non-display region NA. Optionally, the second compensation signal line 402 may be connected to the negative power bus Z2 in the non-display region NA through a via in the non-display region NA, thereby achieving electrical connection between the second compensation signal line 402 and the second power signal line 30. In one embodiment, the second compensation signal line 402 may be configured in the non-display region NA to be connected to the negative power bus Z2 of the non-display region NA through a via. In such way, the via may be in the non-display region NA, which may be beneficial for reducing the number of vias in the display region AA as possible, preventing excessive number of vias in the display region AA from affecting the display uniformity and further improving the display quality.

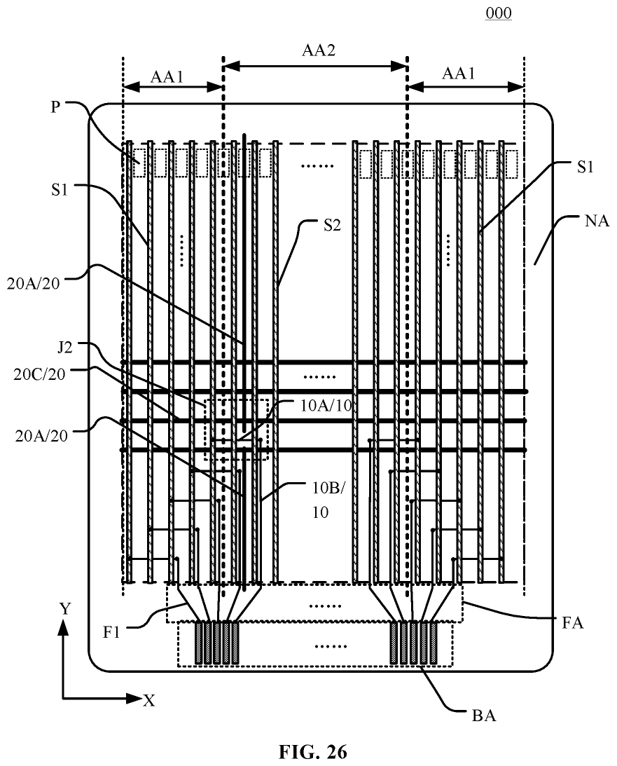

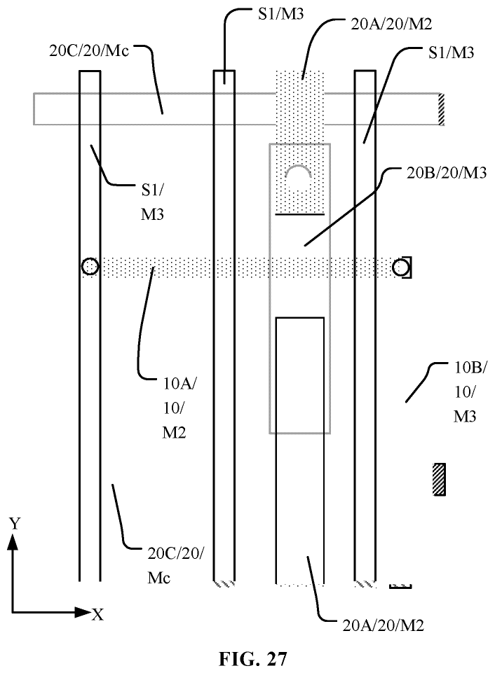

In some optional embodiments, referring to FIGS. 26-27, FIG. 26 illustrates another planar structural schematic of the display panel according to various embodiments of the present disclosure; and FIG. 27 illustrates a local enlarged structural schematic of a J2 region in FIG. 26. It may be understood that, in order to clearly illustrate the structure in one embodiment, transparency filling is performed in FIG. 27. In one embodiment, the first power signal line 20 for providing a positive power signal may further include the third conductive line 20C. The third conductive line 20C and the first conductive line 20A may be disposed in different layers; the third conductive line 20C and the second conductive line 20B may be disposed in different layers; the third conductive line 20C may extend along the second direction X; and the third conductive line 20C may be electrically connected to the first conductive line 20A, where the first direction Y may intersect the second direction X. In one embodiment, the first direction Y and the second direction X may be perpendicular to each other as an example for illustration.

In one embodiment, it describes that the first power signal line 20 in the display panel 000 may further include the third conductive line 20C. The film layer of the third conductive line 20C may be different from the film layers of the first conductive line 20A and the second conductive line 20B. Moreover, the extension direction of the third conductive line 20C may be also different from the extension directions of the first conductive line 20A and the second conductive line 20B. In one embodiment, the first conductive line 20A and the second conductive line 20B extending along the first direction Y may be overlapped and electrically connected with each other, such that the third conductive line 20C may extend along the second direction X. Optionally, the first conductive line 20A may be in the second metal layer M2, and the second conductive line 20B may be in the third metal layer M3, such that the third conductive line 20C may be fabricated using the capacitor metal layer Mc. Therefore, the third conductive line 20C, extending along the second direction X, and the first conductive line 20A and the second conductive line 20B, extending along the first direction Y, may form the first power signal line 20 of the grid structure, which may be beneficial for further reducing the impedance of overall first power signal line 20 in the display panel 000 and ensuring the transmission stability and display uniformity of the positive power signal.

Optionally, referring to FIGS. 4, 5 and 8, the pixel circuit 01 included in the display panel 000 may take the circuit connection structure shown in FIG. 4 and the circuit layout shown in FIG. 5 as examples. The display panel 000 may include a plurality of first reference voltage signal lines REF1 (which may be understood as first reset signal lines REF1). The first reference voltage signal line REF1 may extend along the second direction X, and the third conductive line 20C may be disposed in a same layer as the first reference voltage signal line REF1.

In one embodiment, it describes that the first power signal line 20 may include the first conductive line 20A, the second conductive line 20B, and the third conductive line 20C which are disposed in different layers. The first conductive line 20A may be in the second metal layer M2 which is same layer as the first sub-segment 10A of the first connection line 10. The second conductive line 20B may be in the third metal layer M3 which is same layer as the second sub-segment 10B of the first connection line 10 and the first data line S1. Therefore, the third conductive line 20C may also be fabricated using the capacitive metal layer Mc that is included in the display panel 000 itself and where the first reference voltage signal line REF1 is located, which may be beneficial for avoiding disposing an additional film layer on the display panel 000 to fabricate the third conductive line 20C, reducing the panel thickness, saving cost and improving process efficiency. The third conductive line 20C in the capacitor metal layer Mc may be electrically connected to the first conductive line 20A in the second metal layer M2, which may also reduce the depth of the via when the third conductive line 20C and the first conductive line 20A are connected through the via, thereby reducing process difficulty.

Optionally, in the pixel circuit structures illustrated in FIGS. 4 and 5, one terminal of the storage capacitor Cst in the capacitor metal layer Mc may be electrically connected to the first power signal line 20, such that it is equivalent that one terminal of the storage capacitor Cst in the capacitor metal layer Mc may be connected to the positive power signal input by the first power signal line 20. Therefore, one terminal of the storage capacitor Cst in the capacitor metal layer Mc may also be reused as a part of segments of the third conductive line 20C. As shown in FIG. 8, one terminal of each of the plurality of storage capacitors Cst in the capacitor metal layer Mc of a same row of pixel circuits may be connected to each other to form the second conductive line 20C extending along the second direction X; and the second conductive line 20C may be electrically connected to the first conductive line 20A in the second metal layer M2 through a via, thereby forming a grid-like structure of the first power signal lines 20. In one embodiment, reusing one terminal of the storage capacitor Cst in the capacitor metal layer Mc as a part of segments of the third conductive line 20C may be beneficial for saving the layout space of the capacitor metal layer Mc, reducing the structure of the capacitor metal layer Mc and reducing the difficulty of the fabrication process.

In some optional embodiments, referring to FIGS. 1, 4, 5, 6-11 and 15-22, the display panel 000 may include a plurality of first reference voltage signal lines RF1 and a plurality of second reference voltage signal lines RF2. The first reference voltage signal line RF1 may extend along the second direction X. It may be understood that the first reference voltage signal line RF1 may be equivalent to the first reset signal line REF1 or the second reset signal line REF2 in the capacitor metal layer Mc and extending along the second direction X in above-mentioned embodiment. The second reference voltage signal line RF2 may extend along the first direction Y. The first reference voltage signal line RF1 and the second reference voltage signal line RF2 may be disposed in different layers. The first direction Y may intersect the second direction X. In one embodiment, the first direction Y and the second direction X may be perpendicular to each other as an example for illustration.

Optionally, referring to FIGS. 11 and 16, a same second reference voltage signal line RF2 may at least include the fourth conductive line RF2A and the fifth conductive line RF2B disposed in different layers; the fourth conductive line RF2A and the fifth conductive line RF2B may both extend along the first direction Y; the fourth conductive line RF2A and the fifth conductive line RF2B may be electrically connected to each other; along the direction perpendicular to the plane of the display panel 000, the fourth conductive line RF2A and the fifth conductive line RF2B may be at least partially overlapped with each other; the first reference voltage signal line RF1 and the first sub-segment 10A may be disposed in different layers; the fourth conductive line RF2A and the first sub-segment 10A may be disposed in a same layer; and the fifth conductive line RF2B and the second sub-segment 10B may be disposed in a same layer.

In one embodiment, it describes that entire display panel 000 may include the plurality of first reference voltage signal lines RF1 extending along the second direction X and the plurality of second reference voltage signal lines RF2 extending along the first direction Y. The first reference voltage signal line RF1 extending along the second direction X may be understood as the first reset signal line REF1 or the second reset signal line REF2 fabricated using the capacitor metal layer Mc in above-mentioned embodiments. A same second reference voltage signal line RF2 extending along the first direction Y may at least include the fourth conductive line RF2A and the fifth conductive line RF2B disposed in different layers and overlapped with each other; and the fourth conductive line RF2A and the fifth conductive line RF2B may be electrically connected to each other. The fourth conductive line RF2A and the first sub-segment 10A of the first connection line 10 may be in a same layer, that is, may both be in the second metal layer M2; and the fifth conductive line RF2B and the second sub-segment 10B of the first connection line 10 may be in a same layer, that is, may both be in the third metal layer M3. Furthermore, the impedance of the second reference voltage signal line RF2 may be reduced through the fourth conductive line RF2A and the fifth conductive line RF2B overlapped and electrically connected to each other, which may be beneficial for further improving the display uniformity and ensuring the display effect.

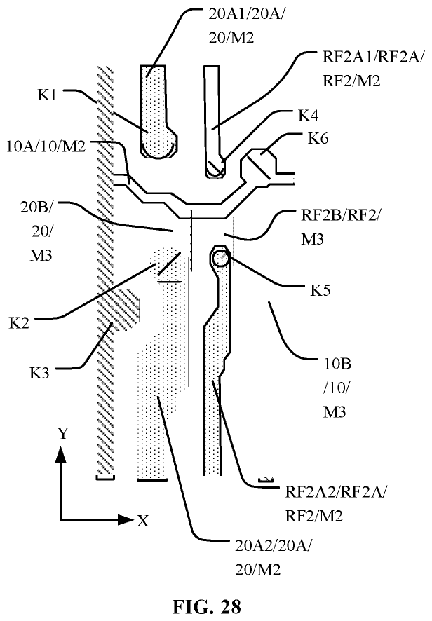

In some optional embodiments, referring to FIGS. 1, 4, 5, 6-11, 15-22 and 28, FIG. 28 illustrates a structural schematic of the first connection line, the first power signal line, the first data line and the second reference voltage signal line in the circuit layout in FIGS. 5 and 15. It may be understood that, in order to clearly illustrate the structure of one embodiment, transparency filling is performed in FIG. 28. In one embodiment, the first reference voltage signal line RF1 may extend along the second direction X; the first reference voltage signal line RF1 may be in the capacitor metal layer Mc (not shown in FIG. 28); the second reference voltage signal line RF2 may extend along the first direction Y; the second reference voltage signal line RF2 may include the fourth conductive line RF2A and the fifth conductive line RF2B disposed in different layers; the fourth conductive line RF2A and the fifth conductive line RF2B may be at least partially overlapped with each other; the fourth conductive line RF2A may be in the second metal layer M2, which is in a same layer as the first sub-segment 10A of the first connection line 10; and the fifth conductive line RF2B may be in the third metal layer M3, which is in a same layer as the second sub-segment 10B of the first connection line 10.

The fourth conductive line RF2A may include the third portion RF2A1 and the fourth portion RF2A2 which are disconnected from each other. Along the first direction Y, the third portion RF2A1 and the fourth portion RF2A2 may be respectively on two opposite sides of the first sub-segment 10A.

The third portion RF2A1 may be electrically connected to the fifth conductive line RF2B through the fourth via K4, and the fourth portion RF2A2 may be electrically connected to the fifth conductive line RF2B through the fifth via K5. Along the first direction Y, the fourth via K4 and the fifth via K5 may be respectively on two opposite sides of the first sub-segment 10A.

In one embodiment, it describes that the first sub-segment 10A of the first connection line 10 and the first conductive line 20A of the first power signal line 20 may be disposed in a same layer and both in the second metal layer M2; the second reference voltage signal line RF2 may include the fourth conductive line RF2A and the fifth conductive line RF2B disposed in different layers which may both extend along the first direction Y; and after the first sub-segment 10A of the first connection line 10 is connected to the first data line S1, the first sub-segment 10A may need to extend to the second display region AA2 along the second direction X. Therefore, at least a part of the first sub-segment 10A of the first connection line 10 may need to extend along the second direction X to be adjacent to the second display region AA2. When the fourth conductive line RF2A of the second reference voltage signal line RF2 extends along the first direction Y, the fourth conductive line RF2A may need to avoid the first sub-segment 10A of the first connection line 10 in a same layer as the fourth conductive line RF2A. In one embodiment, it configures that the fourth conductive line RF2A extending along the first direction Y may include the third portion RF2A1 and the fourth portion RF2A2 which are disconnected from each other; and the third portion RF2A1 and the fourth portion RF2A2 may be respectively on two opposite sides of the first sub-segment 10A. Therefore, the third portion RF2A1 and the fourth portion RF2A2 which are disconnected from each other may avoid the first sub-segment 10A in a same layer as the fourth conductive line RF2A. Furthermore, the fourth conductive line RF2A of the second metal layer M2 and the fifth conductive line RF2B of the third metal layer M3 may be electrically connected, which may satisfy reduced impedance of the second reference voltage signal line RF2 and may also avoid the short circuit problem between the fourth conductive line RF2A and the first sub-segment 10A which are in a same layer, thereby ensuring the fabrication yield.

Optionally, the third portion RF2A1 of the fourth conductive line RF2A may be electrically connected to the fifth conductive line RF2B through the fourth via K4, and the fourth portion RF2A2 may be electrically connected to the fifth conductive line RF2B through the fifth via K5; and along the first direction Y, the fourth via K4 and the fifth via K5 may be respectively on two opposite sides of the first sub-segment 10A.

In one embodiment, it describes that the fourth conductive line RF2A and the fifth conductive line RF2B in different layers may be electrically connected through vias. For example, the fourth conductive line RF2A includes the disconnected third portion RF2A1 and the fourth portion RF2A2; and along the first direction Y, the third portion RF2A1 on one side of the first sub-segment 10A is electrically connected to the fifth conductive line RF2B of the third metal layer M3 through the fourth via K4. In such way, the fifth conductive line RF2B in the third metal layer M3 crosses the first sub-segment 10A of the first connection line 10. Then, on another side of the first sub-segment 10A, the fourth portion RF2A2 of the fourth conductive line RF2A is electrically connected to the fifth conductive line RF2B of the third metal layer M3 through the fifth via K5. The electrical connection between the third portion RF2A1 on the second metal layer M2 on the side of the first sub-segment 10A, the fifth conductive line RF2B in the third metal layer M3 across the first sub-segment 10A and the fourth portion RF2A2 on the second metal layer M2 on another side of the first sub-segment 10A may be realized. It may also be satisfied that the third portion RF2A1 and the fifth conductive line RF2B at least partially overlap, and the fourth portion RF2A2 and the fifth conductive line RF2B at least partially overlap, while reducing the impedance of the second reference voltage signal line RF2. It is also possible to avoid the short circuit problem between the fourth conductive line RF2A and the first sub-segment 10A in a same layer by disconnecting the third RF2A1 and the fourth RF2A2, thereby ensuring the fabrication yield.

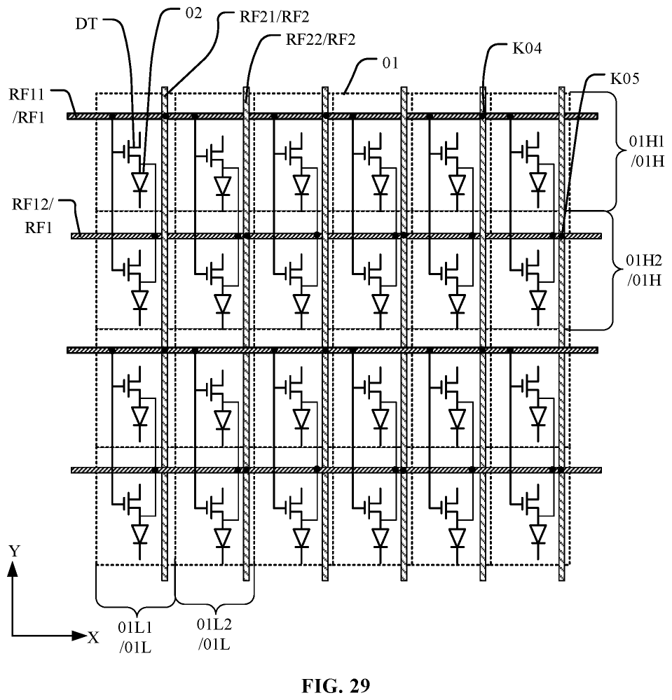

In some optional embodiments, referring to FIGS. 1, 4, 5, 6-11, 15-22 and 29, FIG. 29 illustrates a structural schematic of an electrical connection relationship between the first reference voltage signal line and the second reference voltage signal line in the display panel according to various embodiments of the present disclosure. It may be understood that, in order to clearly illustrate the structure of one embodiment, FIG. 29 only illustrates the structure of the first reference voltage signal line and the second reference voltage signal line in the display panel; the layout structure of the pixel circuit is omitted; a dotted box is used to indicate the layout of the pixel circuit; and transparency filling is performed in FIG. 29. In one embodiment, the display region AA may include the plurality of pixel circuits 01 arranged in an array. A plurality of pixel circuits arranged along the second direction X may form a pixel circuit row 01H; a plurality of pixel circuit rows 01H may be arranged along the first direction Y; a plurality of pixel circuits 01 arranged along the first direction Y may form a pixel circuit column 01L; and a plurality of pixel circuit columns 01L may be arranged along the second direction X. The pixel circuit 01 may at least include the driving transistor DT and the light-emitting element 02 (as shown in FIGS. 4 and 5) which are electrically connected to each other.

The plurality of first reference voltage signal lines RF1 may at least include two lines including the first sub-signal line RF11 and second sub-signal line RF12 disposed adjacently along the first direction Y. The first sub-signal line RF11 may be electrically connected to the gate electrodes of the driving transistors DT in two adjacent pixel circuit rows 01H (the first pixel circuit row 01H1 and the second pixel circuit row 01H2 as shown in FIG. 29). The second sub-signal line RF12 may be electrically connected to the anodes of the light-emitting elements 02 in two adjacent pixel circuit rows 01H (the first pixel circuit row 01H1 and the second pixel circuit row 01H2 as shown in FIG. 29).

The plurality of second reference voltage signal lines RF2 may at least include two lines including the third sub-signal line RF21 and the fourth sub-signal line RF22 disposed adjacently along the second direction Y. The third sub-signal line RF21 may be electrically connected to the gate electrodes of the driving transistors DT in two adjacent pixel circuit columns 01L (the first pixel circuit column 01L1 and the second pixel circuit column 01L2 as shown in FIG. 29). The fourth sub-signal line RF22 may be electrically connected to the anodes of the light-emitting elements 02 in two adjacent pixel circuit columns 01L (the first pixel circuit column 01L1 and the second pixel circuit column 01L2 as shown in FIG. 29).

In one embodiment, it describes that two adjacent pixel circuit rows 01H may share one first sub-signal line RF11 for resetting the gate electrodes of the driving transistors DT, two adjacent pixel circuit rows 01H may share one second sub-signal line RF12 for resetting the anodes of the light-emitting elements 02, and the first sub-signal line RF11 and the second sub-signal line RF12 may both be in the capacitor metal layer Mc; and two adjacent pixel circuit columns 01L may share one third sub-signal line RF21 for resetting the gate electrodes of the driving transistors DT, two adjacent pixel circuit columns 01L may share one fourth sub-signal line RF22 for resetting the anodes of the light-emitting elements 02, the third sub-signal line RF21 may include electrical connection structures which are in the second metal layer M2 and the second metal layer M3 and overlapped in different layers, and the fourth sub-signal line RF22 may include electrical connection structures which are in the second metal layer M2 and the second metal layer M3 and overlapped in different layers (such as the structure of the second reference voltage signal line in above-mentioned embodiment). Optionally, the first sub-signal line RF11 extending along the second direction X and the third sub-signal line RF21 extending along the first direction Y may be electrically connected through a via (e.g., K04 shown in FIG. 29) at the intersection position, such that the reference voltage signal lines formed for resetting the gate electrodes of the driving transistors DT may be formed into a grid-like structure. Similarly, the second sub-signal line RF12 extending along the second direction X and the fourth sub-signal line RF22 extending along the first direction Y may be electrically connected through a via (e.g., K05 shown in FIG. 29) at the intersection position, such that the reference voltage signal lines for resetting the anodes of the light-emitting elements 02 may be formed into a grid-like structure. Therefore, the impedance of the reference voltage signal lines in the display panel 000 may be reduced, and also the total number of reference voltage signal lines in the panel may be reduced to facilitate spatial layout.

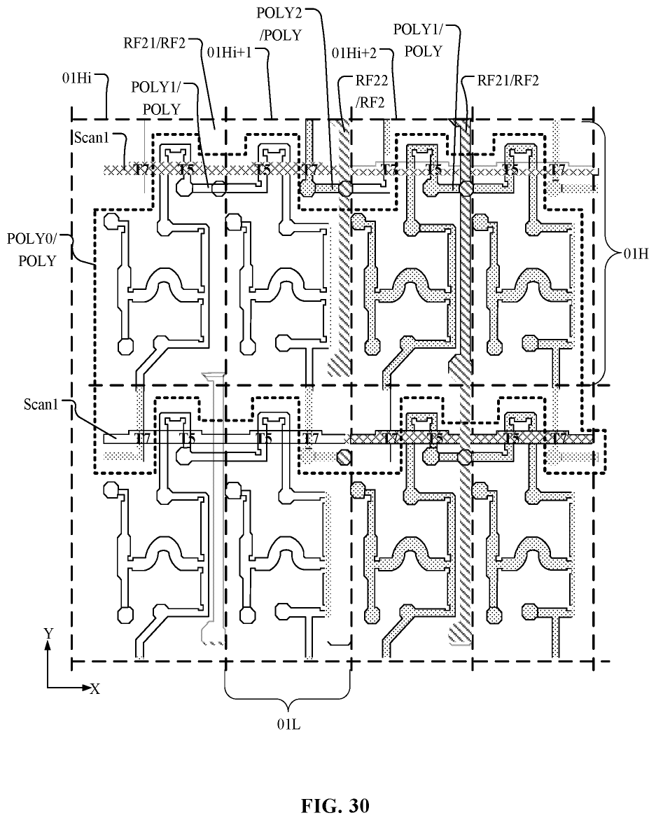

In some optional embodiments, referring to FIGS. 1, 4, 5, 6-11, 15-22 and 30, FIG. 30 illustrates a structural schematic of an electrical connection relationship between the semiconductive layer, the first scanning signal line and the second reference voltage signal line in the display panel according to various embodiments of the present disclosure. It may be understood that, in order to clearly illustrate the structure of one embodiment, FIG. 30 only illustrates the structure of the semiconductive layer, the first scanning signal line and the second reference voltage signal line in the display panel; the layout structure of the pixel circuit is omitted; a dotted box is used to indicate the layout of the pixel circuit; and transparency filling is performed in FIG. 30. In one embodiment, the pixel circuit 01 may include the first reset transistor (i.e., the fifth transistor T5 shown in FIGS. 4 and 5) and the second reset transistor (i.e., the seventh transistor T7 shown in FIGS. 4 and 5). The first reset transistor may be electrically connected to the gate electrode of the driving transistor DT, and the second reset transistor may be electrically connected to the anode of the light emitting element 02. The pixel circuit 01 may include an active portion POLY0 which is in the semiconductive layer POLY.

The pixel circuit row 01H may at least include the i-th pixel circuit 01Hi, the (i+1)-th pixel circuit 01Hi+1, and the (i+2)-th pixel circuit 01Hi+2.

The first electrode of the first reset transistor of the i-th pixel circuit 01Hi may be connected to the first electrode of the first reset transistor (i.e., the fifth transistor T5 shown in FIGS. 4 and 5) of the (i+1)-th pixel circuit 01Hi+1 through the second connection line POLY1. The first electrode of the second reset transistor (i.e., the seventh transistor T7 shown in FIGS. 4 and 5) of the (i+1)-th pixel circuit 01Hi+1 may be connected to the first electrode of the second reset transistor of the (i+2)-th pixel circuit 01Hi+2 through the third connection line POLY2.

The second connection line POLY1 and the third connection line POLY1 may be disposed in a same layer as the active portion POLY0, and both may be in the semiconductive layer POLY, where i is a positive integer.

The active portions POLY0 of two adjacent pixel circuit rows may be independent of each other.

In one embodiment, it describes that, in the same pixel circuit row 01H, the first electrode of the fifth transistor T5 of the i-th pixel circuit 01Hi may be connected to the first electrode of the fifth transistor T5 of the (i+1)-th pixel circuit 01Hi+1 through the second connection line POLY1 in the semiconductive layer POLY, and may be electrically connected to the third sub-signal line RF21 of the second reference voltage signal line RF2 through the second connection line POLY1; the reset signal may be simultaneously transmitted to the fifth transistors T5 (i.e., the first reset transistor) of two adjacent pixel circuit columns 01L through the third sub-signal line RF21; and the reset signal may be simultaneously provided to the gate electrodes of the driving transistors DT of two adjacent pixel circuit columns 01L.

The first electrode of the seventh transistor T7 of the (i+1)-th pixel circuit 01Hi+1 may be connected to the first electrode of the second reset transistor (i.e., the seventh transistor T7 shown in FIGS. 4 and 5) of the (i+2)-th pixel circuit 01Hi+2 through the third connection line POLY2 in the semiconductive layer POLY. The reset signal may be simultaneously transmitted to the seventh transistor T7 (i.e., the second reset transistor) of two adjacent pixel circuit columns 01L through the fourth sub-signal line RF22; and the reset signal may be simultaneously provided to the anodes of the light-emitting elements 02 of two adjacent pixel circuit columns 01L.

In one embodiment, it describes that, in two adjacent pixel circuit rows 01H, the reset signal connected to the gate electrode of the driving transistor DT in a previous row may be different from the reset signal connected to the anode of the light-emitting element 02 in a next row, such that the active portions of the semiconductive layers POLY in adjacent pixel circuit rows 01H may need to be independent of each other to avoid interference between the reset signals after connection. In addition, the active portions of the semiconductive layers POLY in a same pixel circuit row 01H may be connected to each other, which may prevent the active portions of a same pixel circuit row 01H from being independent from each other to cause local charge accumulation and affecting the transistor performance in the pixel circuits in the local region, and may avoid affecting the transistor performance during the formation process by the factors such as static charges, thereby avoiding uneven display on the display panel and improving display quality.

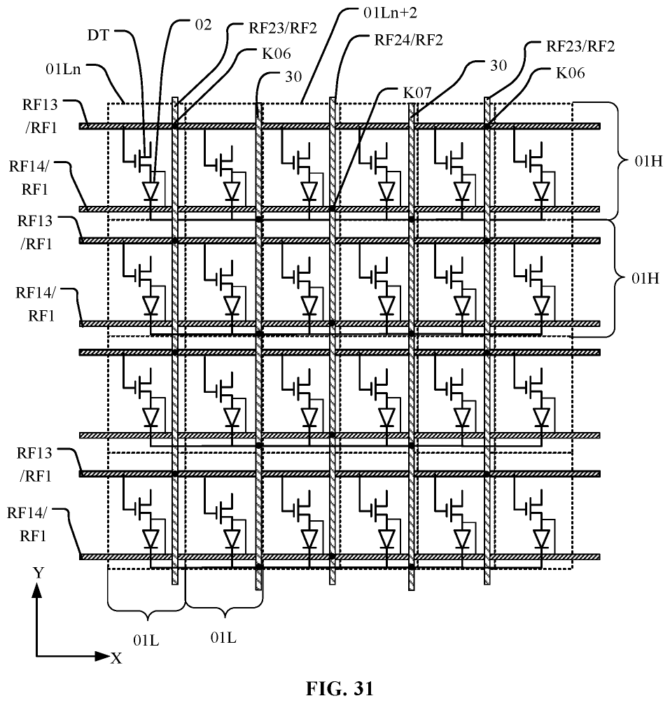

In some optional embodiments, referring to FIGS. 1, 4, 5, 6-11, 15-22, and 31, FIG. 31 illustrates another structural schematic of an electrical connection relationship between the first reference voltage signal line and the second reference voltage signal line in the display panel according to various embodiments of the present disclosure. It may be understood that, in order to clearly illustrate the structure of one embodiment, FIG. 31 only illustrates the structure of the first reference voltage signal line and the second reference voltage signal line in the display panel; the layout structure of the pixel circuit is omitted; a dotted box is used to indicate the layout of the pixel circuit; and transparency filling is performed in FIG. 30. In one embodiment, the display region AA may include the plurality of pixel circuits 01 arranged in an array. The plurality of pixel circuits 01 arranged along the second direction X may form the pixel circuit row 01H. The plurality of pixel circuit rows 01H may be arranged along the first direction Y. The plurality of pixel circuits 01 arranged along the first direction Y may form the pixel circuit column 01L. The plurality of pixel circuit columns 01L may be arranged along the second direction X.

The pixel circuit 01 may at least include the driving transistor DT and a light-emitting element 02 which are electrically connected to each other.

The plurality of first reference voltage signal lines RF1 may at least include two lines including the fifth sub-signal line RF13 and the sixth sub-signal line RF14 arranged adjacently along the first direction Y. The fifth sub-signal line RF13 may be electrically connected to the gate electrode of the driving transistor DT in a pixel circuit row 01H. The sixth sub-signal line RF14 may be electrically connected to the anode of the light-emitting element 02 in a same pixel circuit row 01H.

The plurality of second reference voltage signal lines RF2 may at least include two lines including the seventh sub-signal line RF23 and the eighth sub-signal line RF24 arranged adjacently along the second direction X. The seventh sub-signal line RF23 may be in the n-th pixel circuit column 01Ln. The eighth sub-signal line RF24 may be in the (n+2)-th pixel circuit column 01Ln+2. The seventh sub-signal line RF23 may be electrically connected to the gate electrodes of the driving transistors DT in four adjacent pixel circuit columns 01L (four adjacent pixel circuit columns as shown in FIG. 31). The eighth sub-signal line RF24 may be electrically connected to the anodes of the light-emitting elements 02 in four adjacent pixel circuit columns 01L (four adjacent pixel circuit columns as shown in FIG. 31), where n is a positive integer.

The display panel 000 may include the plurality of second power signal lines 30 extending along the first direction Y. The second power signal line 30 and the second reference voltage signal line RF2 may be arranged in a same layer. The second power signal line 30 may be between the seventh sub-signal line RF23 and the eighth sub-signal line RF24.

The fifth sub-signal line RF13 and the seventh sub-signal line RF23 may be electrically connected through a via (e.g., K06 in FIG. 31). The sixth sub-signal line RF14 and the eighth sub-signal line RF24 may be electrically connected through a via (e.g., K07 in FIG. 31).

In one embodiment, it describes that four adjacent pixel circuit columns 01L may share one seventh sub-signal line RF23 for resetting the gate electrodes of the driving transistors DT, and four adjacent pixel circuit columns 01L may share one eighth sub-signal line RF24 for resetting the anodes of the light-emitting elements 02. The seventh sub-signal line RF23 may include electrical connection structures which are in the second metal layer M2 and the second metal layer M3 and overlapped in different layers. The eighth sub-signal line RF24 may include electrical connection structures which are in the second metal layer M2 and the second metal layer M3 and overlapped in different layers (such as the structure of the second reference voltage signal line in above-mentioned embodiment). Same pixel circuit row 01H may be configured with two first reference voltage signal lines RF1 which are respectively the fifth sub-signal line RF13 configured to reset the gate electrodes of the driving transistors DT of the pixel circuit row 01H, and the sixth sub-signal line RF14 configured to reset the anodes of the light-emitting elements 02 of the pixel circuit row 01H. The fifth sub-signal line RF13 and the sixth sub-signal line RF14 may both be in the capacitor metal layer Mc. Optionally, the fifth sub-signal line RF13 extending along the second direction X and the seventh sub-signal line RF23 extending along the first direction Y may be electrically connected through a via (e.g., K06 shown in FIG. 31) at the intersection position, such that the reference voltage signal lines for resetting the gate electrodes of the driving transistors DT may be formed into a grid-like structure. Similarly, the sixth sub-signal line RF14 extending along the second direction X and the eighth sub-signal line RF24 extending along the first direction Y may be electrically connected through a via (e.g., K07 shown in FIG. 31) at the intersection position, such that the reference voltage signal lines for resetting the anodes of the light-emitting elements 02 may be formed into a grid-like structure, which may not only reduce the impedance of the reference voltage signal lines in the display panel 000, but also reduce total number of reference voltage signal lines in the panel to facilitate spatial layout.

In one embodiment, four adjacent pixel circuit columns 01L may share one seventh sub-signal line RF23 for resetting the gate electrodes of the driving transistors DT, and four adjacent pixel circuit columns 01L may share one eighth sub-signal line RF24 for resetting the anodes of the light-emitting elements 02. Therefore, an extra space for disposing the third power signal line 30 may be at the position of the pixel circuit column (e.g., Ln+1 position at the pixel circuit column 01 in FIG. 31) between the seventh sub-signal line RF23 and the eighth sub-signal line RF24. The third power signal line 30 may be electrically connected to the cathode of the light-emitting element 02 to provide a negative power signal for the pixel circuit, which may provide more space for arranging the third power signal line 30 and be beneficial for reducing the arrangement difficulty of the circuit layout.

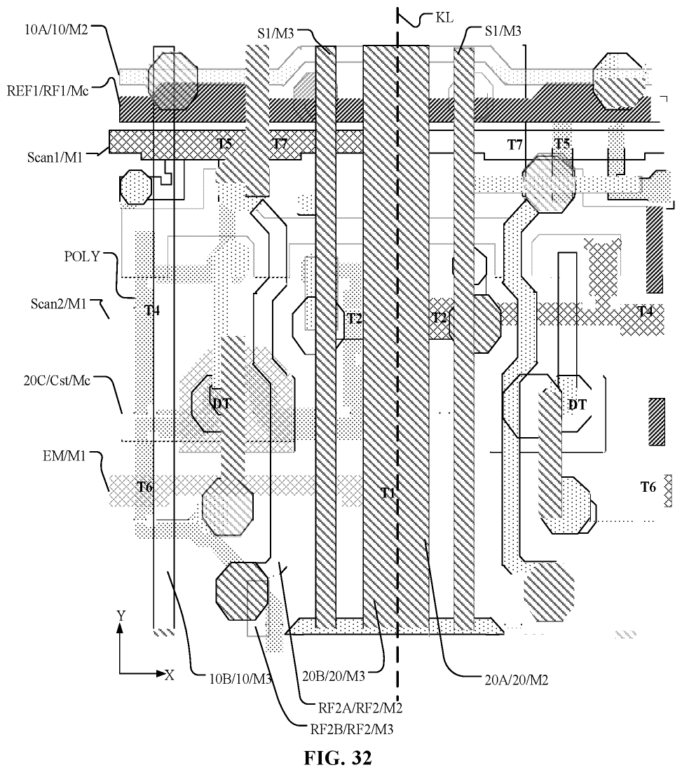

In some optional embodiments, referring to FIGS. 1, 2, 4 and 32, FIG. 32 illustrates another circuit layout when the pixel circuit structure in FIG. 4 is formed on the substrate of the display panel. It may be understood that, in order to clearly illustrate the structure in one embodiment, transparency filling is performed in FIG. 32. In one embodiment, the display region AA may include the plurality of pixel circuits 01 arranged in an array, and two adjacent pixel circuits 01 in a same row may be arranged in mirror symmetry.

Optionally, the plurality of pixel circuits 01 may include the first pixel circuit 011 and the second pixel circuit 012. The first pixel circuit 011 and the second pixel circuit 012 may be arranged adjacently along the second direction X. Along the first symmetry axis KL, the first pixel circuit 011 and the second pixel circuit 012 may be symmetrically arranged. It may be understood that the first symmetry axis KL is a virtual structure in the panel, which may be only used to illustrate the symmetrical arrangement of the first pixel circuit 011 and the second pixel circuit 012. The first pixel circuit 011 and the second pixel circuit 012 may be connected to a same first power supply signal line 20.

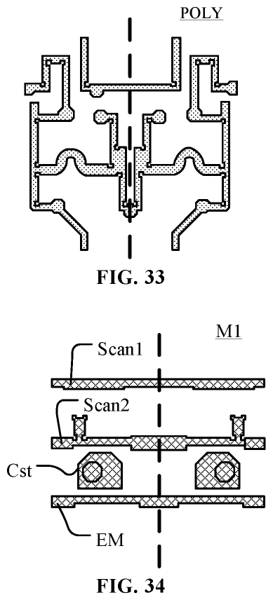

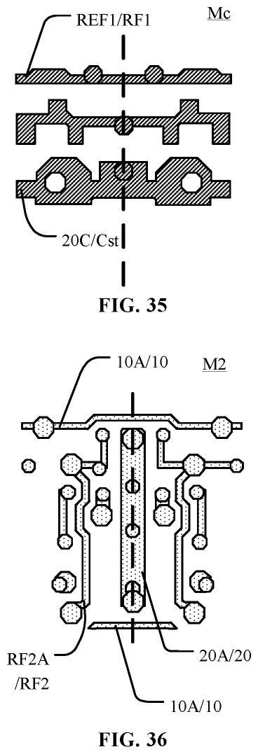

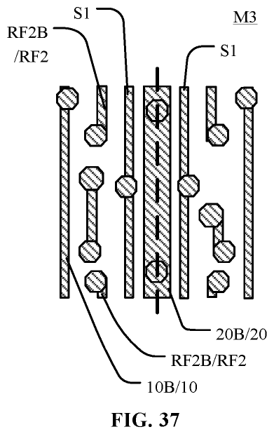

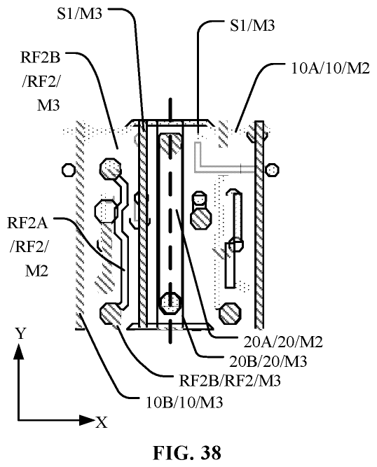

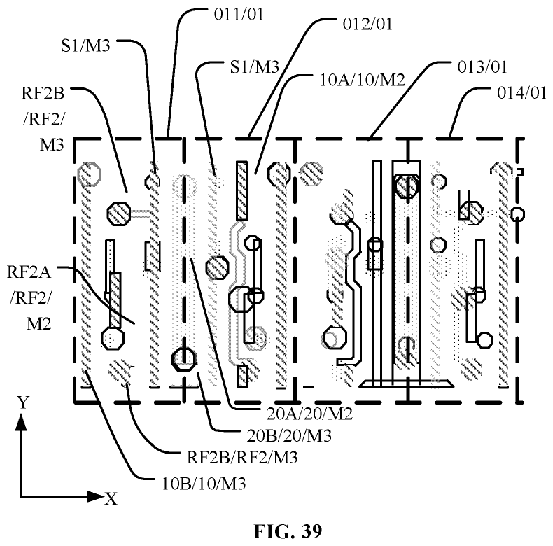

In one embodiment, the pixel circuit 01 included in the display panel 000 may be the circuit connection structure in FIG. 4 as an example, and two adjacent pixel circuits 01 in a same row may be arranged in mirror symmetry. Referring to FIGS. 33-37, FIG. 33 illustrates a structural schematic of the semiconductive layer in FIG. 32; FIG. 34 illustrates a structural schematic of the first metal layer in FIG. 32; FIG. 35 illustrates a structural schematic of the capacitor metal layer in FIG. 32; FIG. 36 illustrates a structural schematic of the second metal layer in FIG. 32; and FIG. 37 illustrates a structural schematic of the third metal layer in FIG. 32. FIGS. 33-37 may be sequentially overlapped to form the layout of the pixel circuit illustrated in FIG. 32. It may be understood that the pixel circuit including two sub-pixels is taken as an example for illustration in FIG. 32. FIG. 38 illustrates a structural schematic of two rows of exemplary pixel circuits after the second metal layer and the third metal layer are overlapped in FIG. 32. Two adjacent pixel circuits 01 in a same row of sub-pixels may be designed to have a mirror-symmetrical structure, such that the first pixel circuit 011 and the second pixel circuit 012 which are mirror symmetrical may be connected to a same first power signal line 20. That is, the first pixel circuit 011 and the second pixel circuit 012 which are mirror symmetrical may share one first power supply signal line 20. Therefore, the first power signal line 20 may not need to be disposed between the second pixel circuit 012 along the second direction X and another pixel circuit on the side away from the first pixel circuit 011. Referring to FIG. 39, FIG. 39 illustrates a structural schematic of four adjacent pixel circuits sequentially arranged after the second metal layer and the third metal layer are overlapped in FIG. 32. FIG. 39 illustrates the structure of four adjacent pixel circuits in a same pixel circuit row. In FIG. 39, the first pixel circuit 011 and the second pixel circuit 012 may be mirror symmetrical, and the third pixel circuit 013 and the fourth pixel circuit 014 may be mirror symmetrical. The first pixel circuit 011 and the second pixel circuit 012 which are mirror symmetrical may share one first power supply signal line 20. Another first power signal line 20 may be disposed between the third pixel circuit 013 and the fourth pixel circuit 014. The third pixel circuit 013 and the fourth pixel circuit 014 may be connected to a same first power signal line 20. The first power signal line 20 may not need to be disposed between the second pixel circuit 012 and the third pixel circuit 013, which may be beneficial for saving the layout space of the signal line, thereby increasing the pixel arrangement density. Meanwhile, the width of a same first power signal line 20 connecting the first pixel circuit 011 and the second pixel circuit 012 which are mirror symmetrical may also be configured to be wide as possible, which may be beneficial for further reducing the impedance of the first power signal line 20 and desirably ensuring the display quality.

It may be understood that, if the layout space allows, the width of the first power signal line 20 in a mirror-symmetrical pixel circuit may be configured to be twice of the width of the first power signal line in a non-mirror-symmetrical pixel circuit, which may not be limited in one embodiment and may only need to satisfy that the width of a same first power signal line 20 connected to the first pixel circuit 011 and the second pixel circuit 012 which are mirror symmetrical may be designed to be wide as possible.

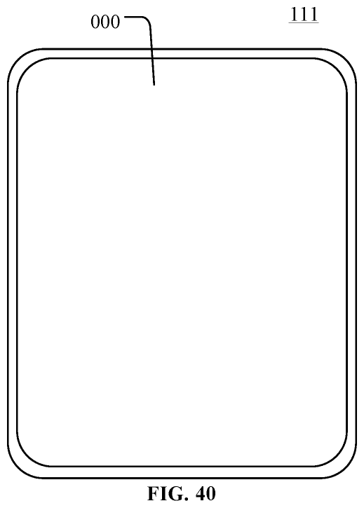

In some optional embodiments, referring to FIG. 40, FIG. 40 illustrates a planar structural schematic of a display apparatus according to various embodiments of the present disclosure. A display apparatus 111 provided in one embodiment may include the display panel 000 provided in above-mentioned embodiment of the present disclosure. Embodiments in FIG. 40 only takes a mobile phone as an example to illustrate the display apparatus 111. It may be understood that the display apparatus 111 provided by embodiments of the present disclosure may be a computer, a television, a vehicle-mounted display apparatus, or other display apparatus 111 with a display function, which may not be limited in the present disclosure. The display apparatus 111 provided by embodiments of the present disclosure may have the beneficial effects of the display panel 000 provided by embodiments of the present disclosure, which may refer to specific description of the display panel 000 in above-mentioned embodiments and may not be limited in one embodiment.

It may be seen from above-mentioned embodiments that the display panel and the display apparatus provided by the present disclosure at least achieve the following beneficial effects.

In the display panel provided by the present disclosure, the display region may be configured with the first connection line that electrically connects the first data line and the fan-out line; in the first sub-segment and the second sub-segment included in a same first connection line, the first sub-segment and the first data line may be disposed in different layers; and the first conductive line of the first power signal line and the first sub-segment of the first connection line may be disposed in a same layer. That is, the first sub-segment of the first connection line may be fabricated using the film layer that is included in the display panel itself and where the first conductive line of the first power signal line is located. The second sub-segment and the first data line may be disposed in a same layer, and the second conductive line of the first power signal line and the second sub-segment of the first connection line may be disposed in a same layer. Therefore, the second sub-segment of the first connection line may be fabricated using the film layer that is included in the display panel itself and where the second conductive line of the first power signal line and the first data line are located. It may be seen that the first sub-segment and the second sub-segment in different film layers included in the first connection line disposed in the display region may be fabricated using the film layer that already exists in the display panel itself; and the display panel may not need to dispose another film layer to fabricate the first connection line in the display region. While achieving narrow frame design, it may also avoid adding extra mask processes and reduce process steps, which may be beneficial for saving overall fabrication cost of the display panel and improving the process efficiency. In the present disclosure, it avoids that additional conductive film layer is disposed in the display panel to fabricate the first connection line. Therefore, it may avoid the coupling problem between new conductive film layer and the conductive structure in the existing film layer of the panel after additional conductive film layer is disposed in the display panel to fabricate the first connection line, which may affect the load of a part of the display region. Disposing additional conductive film layer may not only easily increase wiring design difficulty, but also easily affect display quality. In addition, by disposing the first power signal line through a different conductive film layer included in the display panel itself, the impedance of the first power signal line may be reduced, such that the line width of the first power signal line may be effectively ensured, which may be beneficial for improving the voltage uniformity of the first power signal line by increasing the line width of the first power signal line and preventing reduced voltage uniformity of the first power signal line due to the increase in the impedance of the first power signal line to affect the display uniformity, thereby satisfying the requirement for improving the display quality. Therefore, the display panel provided by the present disclosure may not only realize narrow frame design, but also achieve the objective of reducing the fabrication cost and improving the display quality.

Although some embodiments of the present disclosure have been described in detail through various embodiments, those skilled in the art should understand that above embodiments may be for illustration only and may not be intended to limit the scope of the present disclosure. Those skilled in the art should understood that modifications may be made to above embodiments without departing from the scope and spirit of the present disclosure. The scope of the present disclosure may be defined by the appended claims.

What is claimed is:

1. A display panel, comprising:
a display region and a non-display region arranged along a first direction, wherein:
the display region includes a plurality of first data lines extending along the first direction; the non-display region includes a plurality of fan-out lines; and a first data line of the plurality of first data lines is electrically connected to a fan-out line of the plurality of fan-out lines through at least one first connection line in the display region; and
a same first connection line includes a first sub-segment and a second sub-segment which are disposed in different layers; one end of the first sub-segment is connected to the first data line, and another end of the first sub-segment is connected to the second sub-segment; the first sub-segment and the first data line are disposed in different layers; and the second sub-segment and the first data line are disposed in a same layer; and
a plurality of first power signal lines, wherein:
a same first power signal line includes a first conductive line and a second conductive line which are disposed in different layers; the first conductive line and the second conductive line both extend along the first direction and are electrically connected to each other; and along a direction perpendicular to a plane of the display panel, the first conductive line is at least partially overlapped with the second conductive line; and
the first conductive line and the first sub-segment are disposed in a same layer; and the second conductive line and the second sub-segment are disposed in a same layer.

2. The display panel according to claim 1, wherein:
the first conductive line includes a first portion and a second portion which are disconnected from each other; and along the first direction, the first portion and the second portion are respectively on two opposite sides of the first sub-segment; and/or
the first portion is electrically connected to the second conductive line through a first via, and the second portion is electrically connected to the second conductive through a second via; and along the first direction, the first via and the second via are respectively on two opposite sides of the first sub-segment.

3. The display panel according to claim 2, wherein:
the first portion is connected to a first extension segment; the second portion is connected to a second extension segment; and the first extension segment and the second extension segment are both disposed in a same layer as the first conductive line; and
along the first direction, the first extension segment and the second extension segment are respectively on two opposite sides of the first sub-segment; the first extension segment is on a side of the first via facing toward the first sub-segment; and the second extension segment is on a side of the second via facing toward the first sub-segment.

4. The display panel according to claim 1, wherein:
at least a part of the first sub-segment extends along a second direction, and the second sub-segment extends along the first direction, wherein the first direction intersects the second direction; and/or
the first sub-segment includes a first sub-portion extending along the second direction and a second sub-portion extending along the first direction; and along the direction perpendicular to the plane of the display panel, the second sub-portion is overlapped with the first data line, and the second sub-portion is electrically connected to the first data line through a third via.

5. The display panel according to claim 1, further including:
a plurality of first compensation signal lines, wherein a first compensation signal line of the plurality of first compensation signal lines and the first sub-segment are disposed in a same layer; an extension direction of the first compensation signal line is same as an extension direction of the first sub-segment; the first compensation signal line and the first sub-segment are insulated from each other; and
the first compensation signal line is electrically connected to a first power signal line of the plurality of first power signal line.

6. The display panel according to claim 5, wherein:
in the non-display region, the first compensation signal line is connected to the first power signal line.

7. The display panel according to claim 1, further including:
a plurality of second compensation signal lines, wherein a second compensation signal line of the plurality of second compensation signal lines and the second sub-segment are disposed in a same layer; an extension direction of the second compensation signal line is same as an extension direction of the second sub-segment; and the second compensation signal line and the second sub-segment are insulated from each other; and
a plurality of second power signal lines, wherein the second compensation signal line is electrically connected to a second power signal line of the plurality of second power signal lines.

8. The display panel according to claim 7, wherein:
in the non-display region, the second compensation signal line is connected to the second power signal line through a via.

9. The display panel according to claim 1, wherein:
the same first power signal line includes a third conductive line, wherein the third conductive line and the first conductive line are disposed in different layers; the third conductive line and the second conductive line are disposed in different layers; and the third conductive line extends along a second direction and is electrically connected to the first conductive line, wherein the first direction intersects the second direction.

10. The display panel according to claim 9, further including:
a plurality of first reference voltage signal lines extending along the second direction, wherein a third conductive line and a first reference voltage signal line of the plurality of first reference voltage signal lines are disposed in a same layer.

11. The display panel according to claim 1, further including:
a plurality of first reference voltage signal lines and a plurality of second reference voltage signal lines, wherein:
the plurality of first reference voltage signal lines extends along a second direction; the plurality of second reference voltage signal lines extends along the first direction; and the plurality of first reference voltage signal lines and the plurality of second reference voltage signal lines are disposed in different layers, wherein the first direction intersects the second direction.

12. The display panel according to claim 11, wherein:
a same second reference voltage signal line at least includes a fourth conductive line and a fifth conductive which are disposed in different layers, wherein the fourth conductive line and the fifth conductive both extend along the first direction; the fourth conductive line is electrically connected to the fifth conductive line; and along the direction perpendicular to the plane of the display panel, the fourth conductive line is at least overlapped with the fifth conductive line;
a first reference voltage signal line of the plurality of first reference voltage signal lines and the first sub-segment are disposed in different layers; and
the fourth conductive line and the first sub-segment are disposed in a same layer; and the fifth conductive line and the second sub-segment are disposed in a same layer.

13. The display panel according to claim 12, wherein:
the fourth conductive line includes a third portion and a fourth portion which are disconnected from each other, wherein along the first direction, the third portion and the fourth portion are respectively on two opposite sides of the first sub-segment;
the third portion is electrically connected to the fifth conductive line through a fourth via, and the fourth portion is electrically connected to the fifth conductive through a fifth via; and
along the first direction, the fourth via and the fifth via are respectively on two opposite sides of the first sub-segment.

14. The display panel according to claim 11, wherein:
the display region includes a plurality of pixel circuits arranged in an array; a plurality of pixel circuits arranged along the second direction forms a pixel circuit row, and a plurality of the pixel circuit rows is arranged along the first direction; and a plurality of the pixel circuits arranged along the first direction forms a pixel circuit column, and a plurality of the pixel circuit columns is arranged along the second direction;
a pixel circuit of the plurality of pixel circuits at least includes a driving transistor and a light-emitting element which are electrically connected to each other;
the plurality of first reference voltage signal lines at least includes a first sub-signal line and a second sub-signal line which are adjacently disposed along the first direction; the first sub-signal line is electrically connected to gate electrodes of driving transistors in two adjacent pixel circuit rows; and the second sub-signal line is electrically connected to anodes of light-emitting elements in two adjacent pixel circuit rows; and
the plurality of second reference voltage signal lines at least includes two sub-signal lines which are a third sub-signal line and a fourth sub-signal line disposed adjacently along the second direction; the third sub-signal line is electrically connected to gate electrodes of driving transistors in two adjacent pixel circuit columns; and the fourth sub-signal line is electrically connected to anodes of light-emitting elements in two adjacent pixel circuit columns.

15. The display panel according to claim 14, wherein:
the first sub-signal line is electrically connected to the third sub-signal line, and the second sub-signal line is electrically connected to the fourth sub-signal line.

16. The display panel according to claim 14, wherein:
the pixel circuit includes a first reset transistor and a second reset transistor, wherein the first reset transistor is electrically connected to a gate electrode of the driving transistor; the second reset transistor is electrically connected to an anode of the light-emitting element; and the pixel circuit includes an active portion;
the pixel circuit row at least includes an i-th pixel circuit, an (i+1)-th pixel circuit, and an (i+2)-th pixel circuit;
a first electrode of a first reset transistor of the i-th pixel circuit is connected to a first electrode of a first reset transistor of the (i+1)-th pixel circuit through a second connection line; and a first electrode of a second reset transistor of the (i+1)-th pixel circuit is connected to a first electrode of a second reset transistor of the (i+2)-th pixel circuit through a third connection line;
the second connection line, the third connection line and the active portion are disposed in a same layer; wherein i is a positive integer; and
active portions of two adjacent pixel circuit rows are independent of each other.

17. The display panel according to claim 11, wherein:
the display region includes a plurality of pixel circuits arranged in an array; a plurality of pixel circuits arranged along the second direction forms a pixel circuit row, and a plurality of the pixel circuit rows is arranged along the first direction; and a plurality of the pixel circuits arranged along the first direction forms a pixel circuit column, and a plurality of the pixel circuit columns is arranged along the second direction;
a pixel circuit of the plurality of pixel circuits at least includes a driving transistor and a light-emitting element which are electrically connected to each other;
the plurality of first reference voltage signal lines at least includes two sub-signal lines which are a fifth sub-signal line and a sixth sub-signal line disposed adjacently along the first direction; the fifth sub-signal line is electrically connected to a gate electrode of a driving transistor in one pixel circuit row; and the sixth sub-signal line is electrically connected to an anode of a light-emitting element in a same pixel circuit row;
the plurality of second reference voltage signal lines at least includes two sub-signal lines which are a seventh sub-signal line and an eighth sub-signal line adjacently disposed along the second direction; the seventh sub-signal line is in a n-th pixel circuit column; the eighth sub-signal line is in a (n+2)-th pixel circuit column; the seventh sub-signal line is electrically connected to gate electrodes of driving transistors in four adjacent pixel circuit columns; and the eighth sub-signal line is electrically connected to anodes of light-emitting elements in four adjacent pixel circuit columns, wherein n is a positive integer; and
the display panel includes a plurality of second power signal lines extending along the first direction, wherein the plurality of second power signal lines and the plurality of second reference voltage signal lines are disposed in a same layer; and a second power signal line is between the seventh sub-signal line and the eighth sub-signal line.

18. The display panel according to claim 1, wherein:
the display region includes a plurality of pixel circuits arranged in an array, and two adjacent pixel circuits in a same row are arranged in a mirror symmetry; and/or
the plurality of pixel circuits includes a first pixel circuit and a second pixel circuit, wherein along a first symmetry axis, the first pixel circuit and the second pixel circuit are symmetrically arranged; and the first pixel circuit and the second pixel circuit are electrically connected to a same first power signal line.

19. The display panel according to claim 1, wherein:
along a second direction, the display region includes a second display region and first display regions on two opposite sides of the second display region; and the first data line is in the first display region, wherein the first direction intersects the second direction.

20. A display apparatus, comprising:
a display panel, comprising:
a display region and a non-display region arranged along a first direction, wherein:
the display region includes a plurality of first data lines extending along the first direction; the non-display region includes a plurality of fan-out lines; and a first data line of the plurality of first data lines is electrically connected to a fan-out line of the plurality of fan-out lines through at least one first connection line in the display region; and
a same first connection line includes a first sub-segment and a second sub-segment which are disposed in different layers; one end of the first sub-segment is connected to the first data line, and another end of the first sub-segment is connected to the second sub-segment; the first sub-segment and the first data line are disposed in different layers; and the second sub-segment and the first data line are disposed in a same layer; and
a plurality of first power signal lines, wherein:
a same first power signal line includes a first conductive line and a second conductive line which are disposed in different layers; the first conductive line and the second conductive line both extend along the first direction and are electrically connected to each other; and along a direction perpendicular to a plane of the display panel, the first conductive line is at least partially overlapped with the second conductive line; and
the first conductive line and the first sub-segment are disposed in a same layer; and the second conductive line and the second sub-segment are disposed in a same layer.
